(19) United States
(12) Patent Application Publication
(10) Pub. No.: US 2008/0171270 A1
(43) Pub. Date: Jul. 17, 2008

(54) Polymers Useful in Photoresist Compositions and Compositions Thereof

(76) Inventors: Munirathna Padmanaban, Bridgewater, NJ (US); Srinivasan Chakrapani, Bridgewater, NJ (US); Ralph R. Dammel, Flemington, NJ (US)

Correspondence Address: ALAN P. KASS;AZ ELECTRONIC MATERIALS USA CORP., 70 MEISTER AVENUE, SOMERVILLE, NJ, 08876, US

(21) Appl. No.: 11/623,335

(22) Filed: Jan. 16, 2007

(51) Int. Cl. G03F 1/00

(52) U.S. Cl. 430/5; 430/270.1; 430/286.1; 528/220

(57) ABSTRACT

The present application relates to a polymer having the formula

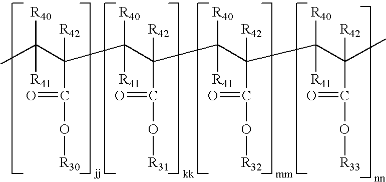

where R₃₀, R₃₁, R₃₂, R₃₃, R₄₀, R₄₁, R₄₂, jj, kk, mm, and nn are described herein. The compounds are useful in forming photoresist compositions.

### FIELD OF INVENTION

The present invention relates to a photoresist composition sensitive to actinic radiation, particularly a positive working photoresist sensitive in the range of 10-300 nanometers (nm). The present invention also relates to polymers useful in such compositions as well as a process for imaging the photoresist composition.

### BACKGROUND OF INVENTION

Photoresist compositions are used in microlithography processes for making miniaturized electronic components such as in the fabrication of computer chips and integrated circuits. Generally, in these processes, a thin coating of film of a photoresist composition is first applied to a substrate material, such as silicon wafers used for making integrated circuits. The coated substrate is then baked to evaporate any solvent in the photoresist composition and to fix the coating onto the substrate. The photoresist coated on the substrate is next subjected to an image-wise exposure to radiation.

The radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation exposed or the unexposed areas of the photoresist.

The trend towards the miniaturization of semiconductor devices has led to the use of new photoresists that are sensitive to lower and lower wavelengths of radiation and has also led to the use of sophisticated multilevel systems to overcome difficulties associated with such miniaturization.

There are two types of photoresist compositions, negative-working and positive-working. When negative-working photoresist compositions are exposed image-wise to radiation, the areas of the resist composition exposed to the radiation become less soluble to a developer solution (e.g. a cross-linking reaction occurs) while the unexposed areas of the photoresist coating remain relatively soluble to such a solution. Thus, treatment of an exposed negative-working resist with a developer causes removal of the non-exposed areas of the photoresist coating and the creation of a negative image in the coating, thereby uncovering a desired portion of the underlying substrate surface on which the photoresist composition was deposited.

On the other hand, when positive-working photoresist compositions are exposed image-wise to radiation, those areas of the photoresist composition exposed to the radiation become more soluble to the developer solution (e.g., a chemical reaction occurs) while those areas not exposed remain relatively insoluble to the developer solution. Thus, treatment of an exposed positive-working photoresist with the developer causes removal of the exposed areas of the coating and the creation of a positive image in the photoresist coating. Again, a desired portion of the underlying surface is uncovered.

Positive working photoresist compositions are currently favored over negative working resists because the former generally have better resolution capabilities and pattern transfer characteristics. Photoresist resolution is defined as the smallest feature which the resist composition can transfer from the photomask to the substrate with a high degree of image edge acuity after exposure and development. In many manufacturing applications today, resist resolution on the order of less than one micron are necessary. In addition, it is almost always desirable that the developed photoresist wall profiles be near vertical relative to the substrate. Such demarcations between developed and undeveloped areas of the resist coating translate into accurate pattern transfer of the mask image onto the substrate. This becomes even more critical as the push toward miniaturization reduces the critical dimensions on the devices.

Photoresists sensitive to short wavelengths, between about 100 nm and about 300 nm can also be used where sub-half micron geometries are required. Particularly preferred are photoresists comprising non-aromatic polymers, one or more photoacid generators (PAG), optionally a solubility inhibitor, and solvent.

High resolution, chemically amplified, deep ultraviolet (100-300 nm) positive and negative tone photoresists are available for patterning images with less than quarter micron geometries. Chemically amplified resists, in which a single photo generated proton catalytically cleaves several acid labile groups, are used in photolithography applicable to sub quarter-micron design rules. As a result of the catalytic reaction, the sensitivity of the resulting resist is quite high compared to the conventional novolak-diazonaphthoquinone resists. To date, there are three major deep ultraviolet (UV) exposure technologies that have provided significant advancement in miniaturization, and these are lasers that emit radiation at 248 nm, 193 nm and 157 nm. Examples of such photoresists are given in the following patents and incorporated herein by reference, U.S. Pat. No. 4,491,628, U.S. Pat. No. 5,350,660, U.S. Pat. No. 5,843,624 and GB 2320718. Photoresists for 248 nm have typically been based on substituted polyhydroxystyrene and its copolymers. On the other hand, photoresists for 193 nm exposure require non-aromatic polymers, since aromatics are opaque at this wavelength. Generally, alicyclic hydrocarbons are incorporated into the polymer to replace the etch resistance lost by the absence of aromatics.

Photoresists based on chemical amplification mechanism are employed for 248 nm, 193 nm, 157 nm, and 13.4 nm applications. However, the resist materials applicable for 248 nm cannot be used at 193 nm due to the high absorption of the poly(4-hydroxystyrene) based polymers used for 248 nm applications. 193 nm applications typically require non-aromatic compounds. Open-chain aliphatic resins cannot be used due to the very high etch rates of these materials. Polymers possessing annelated structures in the side chains such as tricyclododecyl or adamantane in the main chain are shown to provide etch resistance close to poly(4-hydroxystyrene) polymers [Nakano et al. Proc. SPIE 3333, 43 (1998), Nozaki et al. J. Photopolym. Sci. & Tech. Vol. 9, 11, (1998), T. I. Wallow et al. Proc. SPIE 3333, 92 (1998), and J. C. Jung et al. Proc. SPIE 3333, 11, (1998)]. A variety of polymerizable groups can be used in the side-chain bearing monomers, including but not limited to acrylates or methacrylates and their higher homologs, cyanoacrylates, or vinyl ethers.

For Extreme UV applications (EUV) at the wavelength of typically 13.4 nm, the absorption of the film is determined only by the atomic composition of the film, and its density, regardless of the chemical nature of the atom's binding. The absorption of the film can thus be calculated as a sum of the atomic inelastic x-ray scattering cross sections f₂. Polymers with high carbon content are found to be suitable due to the comparatively low f₂ factor for carbon; a high oxygen content is unfavorable for absorption because of the high f₂ factor for oxygen. Since the chemical nature of the carbon atom binding does not matter, aromatic units, e.g., phenols such a polyhydroxystyrene (PHS) and its derivatives can and have been used.

U.S. Published patent application Nos 20050147915, 20060063107, and 20060057496 disclose photoresist compositions using diamantane and other diamondoids.

### SUMMARY OF THE INVENTION

The present invention relates to a polymer having the formula

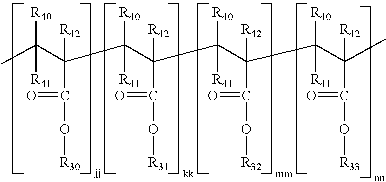

where
R₃₀ is selected from

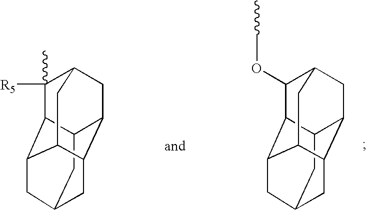

R₃₁ is a polycycloalkyl group substituted with one or more hydroxyl groups;
R₃₂ is an unsubstituted or substituted monocycloalkyl or polycycloalkyl lactone;
R₃₃ is selected from R₃₂, unsubstituted or substituted alkyl, unsubstituted or substituted monocylcoalkyl, and unsubstituted or substituted polycycloalkyl groups;
R₅ is selected from unsubstituted or substituted alkyl, unsubstituted or substituted alkoxy, unsubstituted or substituted monocylcoalkyl, and unsubstituted or substituted polycycloalkyl groups;
R₄₀, R₄₁, and R₄₂ are each selected from hydrogen and unsubstituted or substituted C₁₋₄ alkyl; and
jj is an integer from 1 to 60; kk is an integer ranging from 0 to 60; mm is an integer ranging from 0 to 60; and nn is an integer ranging from 0 to 60, where jj+kk+mm+nn=100.

The invention also relates to a photoresist composition which incorporates the inventive polymer. The invention also relates to a process of imaging the positive photoresist composition of the present invention comprising the steps of a) coating a substrate with the photoresist composition, b) baking the substrate to substantially remove the solvent, c) imagewise irradiating the photoresist film, d) optionally postexposure baking the photoresist, and e) developing the irradiated film using an aqueous alkaline developer. The invention also relates to a coated substrate formed from the photoresist composition which incorporates the inventive polymer.

### DETAILED DESCRIPTION OF THE INVENTION

The present invention relates to a polymer having the formula

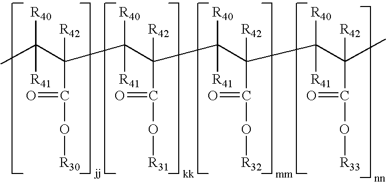

where
R₃₀ is selected from

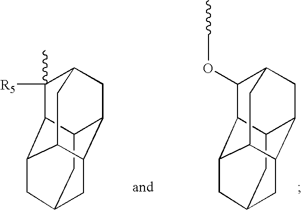

R₃₁ is a polycycloalkyl group substituted with one or more hydroxyl groups;
R₃₂ is an unsubstituted or substituted monocycloalkyl or polycycloalkyl lactone;
R₃₃ is selected from R₃₂, unsubstituted or substituted alkyl, unsubstituted or substituted monocylcoalkyl, and unsubstituted or substituted polycycloalkyl groups;
R₅ is selected from unsubstituted or substituted alkyl, unsubstituted or substituted alkoxy, unsubstituted or substituted monocylcoalkyl, and unsubstituted or substituted polycycloalkyl groups;
R₄₀, R₄₁, and R₄₂ are each selected from hydrogen and unsubstituted or substituted C₁₋₄ alkyl; and
jj is an integer from 1 to 60; kk is an integer ranging from 0 to 60; mm is an integer ranging from 0 to 60; and nn is an integer ranging from 0 to 60, where jj+kk+mm+nn=100.

The invention also relates to a photoresist composition which incorporates the inventive polymer. The invention also relates to a process of imaging the positive photoresist composition of the present invention comprising the steps of a) coating a substrate with the photoresist composition, b) baking the substrate to substantially remove the solvent, c) imagewise irradiating the photoresist film, d) optionally postexposure baking the photoresist, and e) developing the irradiated film using an aqueous alkaline developer. The invention also relates to a coated substrate formed from the photoresist composition which incorporates the inventive polymer.

Diamantane containing polymers have been reported to improve the etch resistance. However, reported polymer compositions do not provide adequate resolution, process window, and line edge roughness (LER) necessary to implement for design rules requiring sub micron resolution needs. A careful combination of hydrophilic and hydrophobic monomers only possess all the properties such as solubility in well accepted resist solvents, film forming properties, resolution, depth of focus (DoF), exposure latitude, (LER) and line width roughness (LWR). In addition, to all the said properties, incorporation of maximum amount of diamantes are necessary to provide the etch resistance. This invention addresses these needs.

The monomers where diamantane is substituent group For example, Schleyer [Journal of Organic Chemistry (1974), 39(20), 2987-94] and McKervey [Synthetic Communications (1973), 3(6), 435-9; Journal of the Chemical Society, Perkin Transactions 1: Organic and Bio-Organic Chemistry (1972-1999) (1972), (21), 2691-6] have described the oxidation of diamantane with sulfuric acid to yield diamantane-3-one. The ketone can be reacted with Grignard reagents such as methyl magnesium bromide or organometallic compounds such as methyl lithium to yield the 3-hydroxy-3-methyl derivative, which can be converted into the methacrylate ester by reaction with methacryloyl chloride. A similar reaction sequence for triamantane starts with the corresponding oxidation reaction to yield triamantane-8-one.

In another example, the reaction of diamantane with sulfuric acid and formic acid, followed by treatment with oxidizing agents such as CrO₃ or HNO₃ in acetic acid leads to a mixture of 9- and 1-hydroxy-substituted diamantane-3-ones [L. Vodicka et al., Coll. Czech. Chem. Commun. 49 (8), 1900-1906 (1984)]. After protection of the hydroxy-function, the ketone can be reacted with Grignard reagents such as methyl magnesium bromide or organometallic compounds such as methyl lithium to yield the 3-hydroxy-3-methyl derivative. The tertiary alcohol is then reacted with methacryloyl chloride to give the methacrylate ester. After removal of the protective group from the primary 9-hydroxy group, the monomer is purified by column chromatography or distillation in a wiped film evaporator.

Di- and trihydroxydiamantanes can be obtained through a variety of oxidation reactions, ranging from the oxidation with sulfuric acid reported by Schleyer, McKervey, and Vodicka, to the treatment of diamantane with lead (IV) acetate in trifluoroacetic acid [S. R. Jones et al., Journal of the Chemical Society, Perkin Transactions 2: Physical Organic Chemistry (1972-1999) (1977), (4), 511-17], to reaction with permanganates [B. P. Leddy et al., Tetrahedron Letters (1980), 21(23), 2261-4], to electrochemical oxidation [A. Berwick et al., Tetrahedron Letters (1976), (8), 631-4]. Normally these reactions lead to a mixture of isomeric di- and trihydroxydiamantanes. An alternative synthesis of the alcohols involves halogenation at the tertiary sites, followed by exchange of the halogens against the hydroxy groups. Substoichiometric esterification of the alcohols with methacryloyl chloride then yields a mixture of esters than can be separated by column chromatography or distillation, preferentially in a wiped film evaporator. It is also possible to use mixtures of different isomeric diamantane di- and tri-ol monomethacrylate esters without isolation of the individual components.

The other monomers that can be combined with the diamantane monomers include (meth)acrylates which are generally based on poly(meth)acrylates with a number of different types of pendant groups, for example, alicyclic groups, and acid labile groups, which can be pendant from the polymer backbone and/or from the alicyclic group. Examples of pendant alicyclic groups, may be adamantyl, tricyclodecyl, isobornyl, menthyl and their derivatives. Other pendant groups may also be incorporated into the polymer, such as mevalonic lactone, gamma butyrolactone, alkyloxyalkyl, etc. Examples of structures for the alicyclic group include:

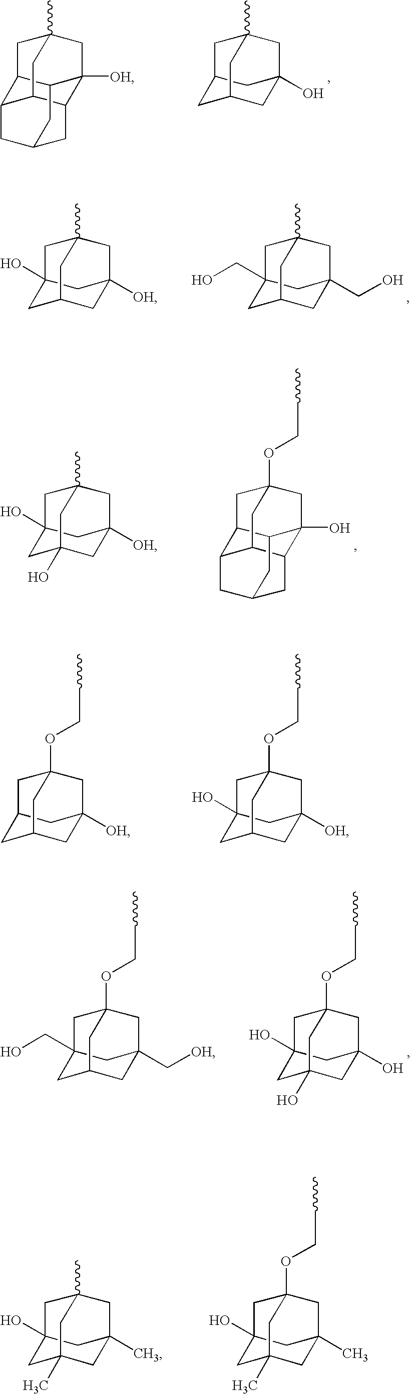

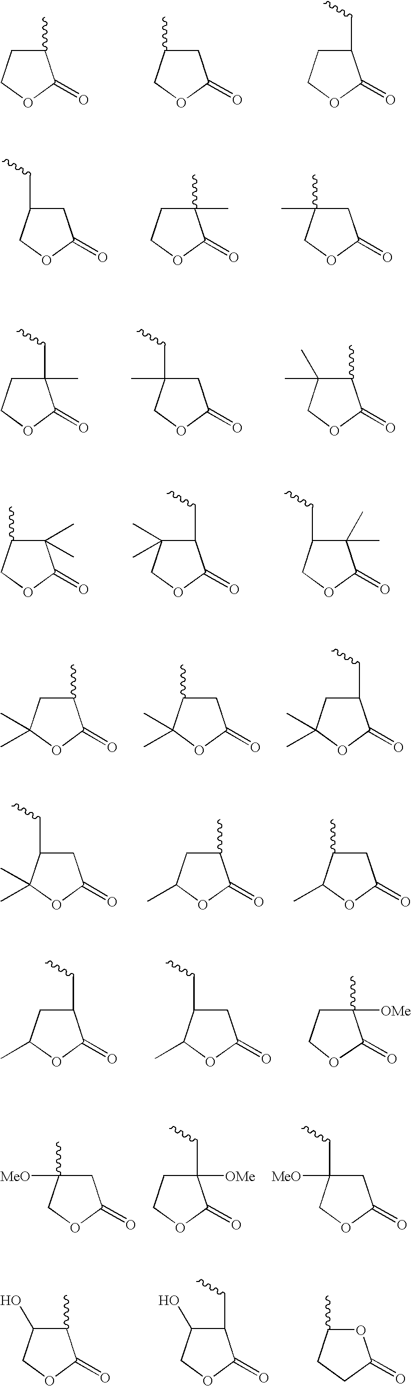

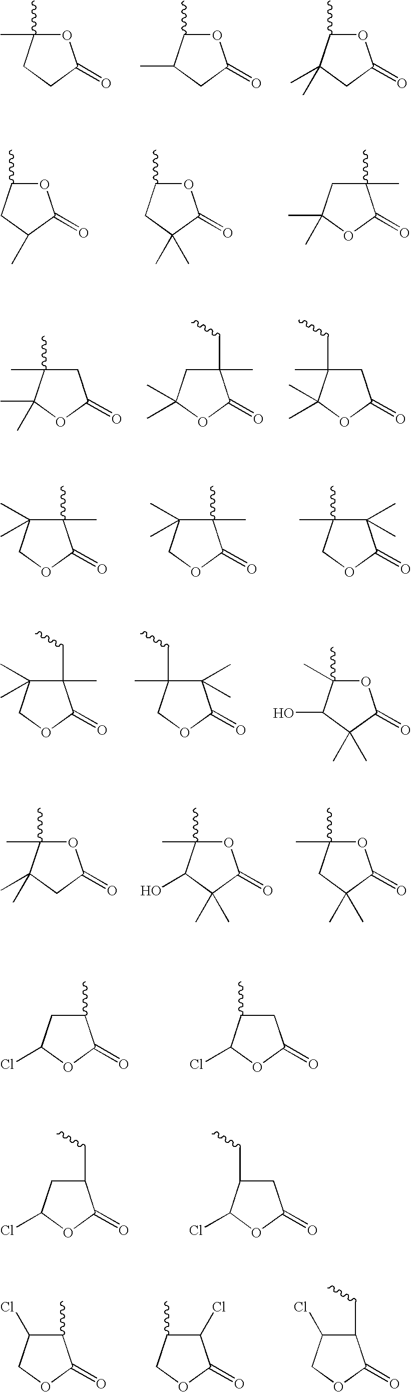

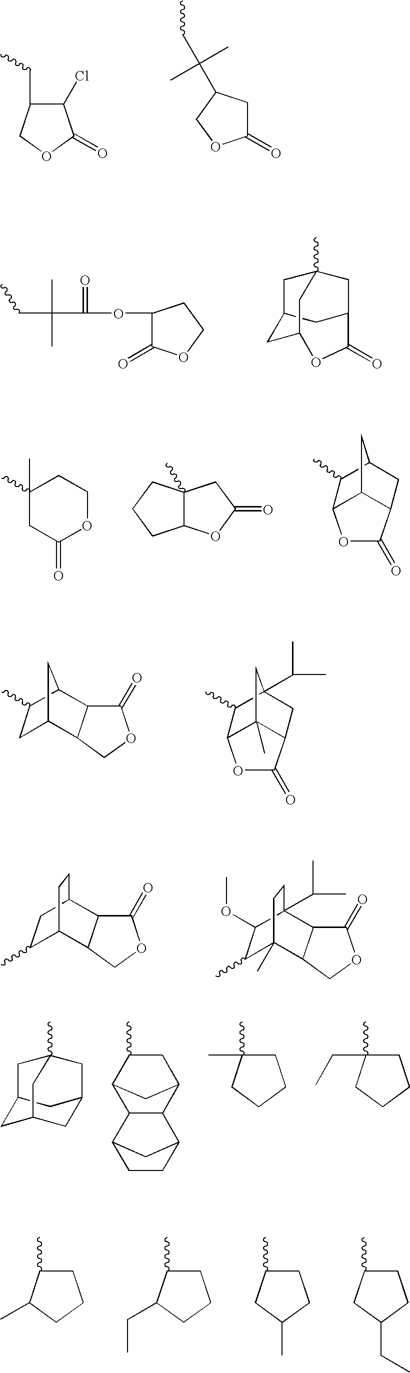

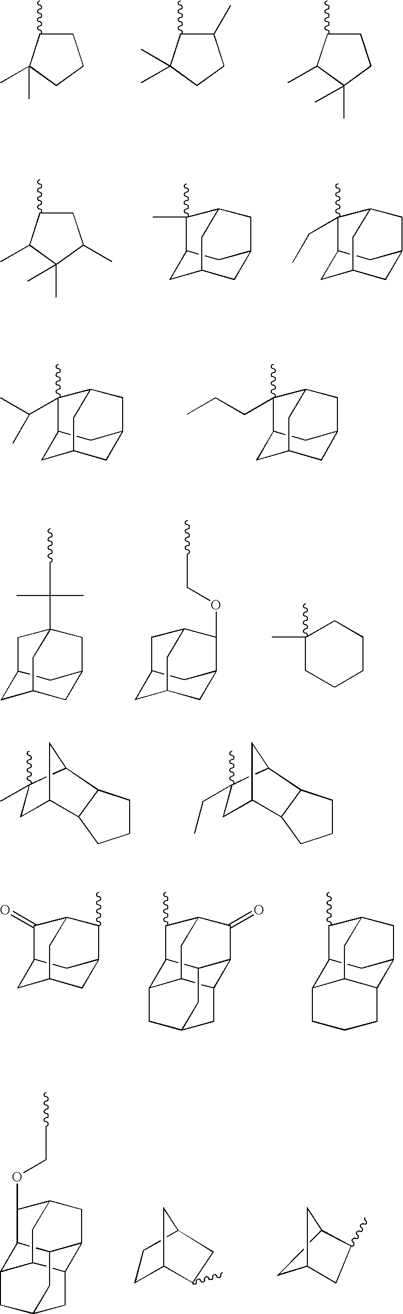

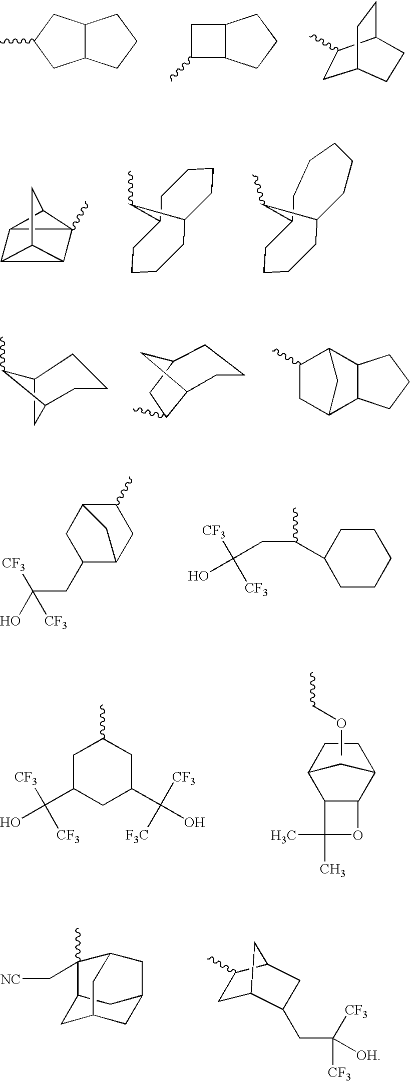

Examples of (meth)acrylate monomers useful in the present invention include those selected from mevalonic lactone methacrylate (MLMA), 2-methyl-2-adamantyl methacrylate (MAdMA), 2-adamantyl methacrylate (AdMA), 2-methyl-2-adamantyl acrylate (MAdA), 2-ethyl-2-adamantyl methacrylate (EAdMA), 3,5-dimethyl-7-hydroxy adamantyl methacrylate (DMHAdMA), isoadamantyl methacrylate, hydroxy-1-methacryloxyadamatane (HAdMA; for example, hydroxy at the 3-position), hydroxy-1-adamantyl acrylate (HADA; for example, hydroxy at the 3-position), ethylcyclopentylacrylate (ECPA), ethylcyclopentylmethacrylate (ECPMA), tricyclo[5,2,1,0^{2,6}]deca-8-yl methacrylate (TCDMA), 3,5-dihydroxy-1-methacryloxyadamantane (DHAdMA), β-methacryloxy-γ-butyrolactone, α- or β-gamma-butyrolactone methacrylate (either α- or β-GBLMA), 5-methacryloyloxy-2,6-norbornanecarbolactone (MNBL), 5-acryloyloxy-2,6-norbornanecarbolactone (ANBL), isobutyl methacrylate (IBMA), α-gamma-butyrolactone acrylate (α-GBLA), spirolactone (meth)acrylate, oxytricyclodecane (meth)acrylate, adamantane lactone (meth)acrylate, and α-methacryloxy-γ-butyrolactone, among others.

Examples of other structures which can be used as R₄, including the aforementioned structures, include, for example,

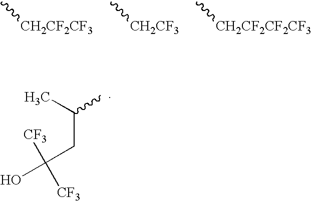

The composition contains, along with the polymer, a mixture of photoacid generators, which are selected from

(i) a compound of formula

(Ai)₂ Xi1,

where each Ai is individually an organic onium cation selected from

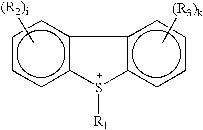

and

Y—Ar

where Ar is selected from

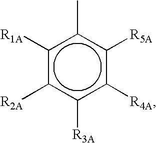

naphthyl, or anthryl;
Y is selected from

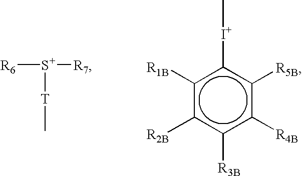

—I⁺-naphtyl, —I⁺-anthryl;

where R₁, R₂, R₃, R_{1A}, R_{1B}, R_{2A}, R_{2B}, R_{3A}, R_{3B}, R_{4A}, R_{4B}, R_{5A}, and R_{5B} are each independently selected from Z, hydrogen, OSO₂R₉, OR₂₀, straight or branched alkyl chain optionally containing one or more O atoms, monocycloalkyl or polycycloalkyl group optionally containing one or more O atoms, monocycloalkyl- or polycycloalkylcarbonyl group, aryl, aralkyl, arylcarbonylmethyl group, alkoxyalkyl, alkoxycarbonylalkyl, alkylcarbonyl, monocycloalkyl- or polycycloalkyloxycarbonylalkyl with the cycloalkyl ring optionally containing one or more O atoms, monocycloalkyl- or polycycloalkyloxyalkyl with the cycloalkyl ring optionally containing one or more O atoms, straight or branched perfluoroalkyl, monocycloperfluoroalkyl or polycycloperfluoroalkyl, straight or branched alkoxy chain, nitro, cyano, halogen, carboxyl, hydroxyl, sulfate, tresyl, or hydroxyl;
R₆ and R₇ are each independently selected from straight or branched alkyl chain optionally containing one or more O atoms, monocycloalkyl or polycycloalkyl group optionally containing one or more O atoms, monocycloalkyl- or polycycloalkylcarbonyl group, aryl, aralkyl, straight or branched perfluoroalkyl, monocycloperfluoroalkyl or polycycloperfluoroalkyl, arylcarbonylmethyl group, nitro, cyano, or hydroxyl or R₆ and R₇ together with the S atom to which they are attached form a 5-, 6-, or 7-membered saturated or unsaturated ring optionally containing one or more O atoms;
R₉ is selected from alkyl, fluoroalkyl, perfluoroalkyl, aryl, fluoroaryl, perfluoroaryl, monocycloalkyl or polycycloalkyl group with the cycloalkyl ring optionally containing one or more O atoms, monocyclofluoroalkyl or polycyclofluoroalkyl group with the cycloalkyl ring optionally containing one or more O atoms, or monocycloperfluoralkyl or polycycloperfluoroalkyl group with the cycloalkyl ring optionally containing one or more O atoms;
R₂₀ is alkoxyalkyl, alkoxycarbonylalkyl, alkylcarbonyl, monocycloalkyl- or polycycloalkyloxycarbonylalkyl with the cycloalkyl ring optionally containing one or more O atoms, or monocycloalkyl- or polycycloalkyloxyalkyl with the cycloalkyl ring optionally containing one or more O atoms;
T is a direct bond, a divalent straight or branched alkyl group optionally containing one or more O atoms, divalent aryl group, divalent aralkyl group, or divalent monocycloalkyl or polycycloalkyl group optionally containing one or more O atoms;
Z is —(V)ⱼ—(C(X11)(X12))ₙ—O—C(═O)—R₈, where either (i) one of X11 or X12 is straight or branched alkyl chain containing at least one fluorine atom and the other is hydrogen, halogen, or straight or branched alkyl chain or (ii) both of X11 and X12 are straight or branched alkyl chain containing at least one fluorine atom;
V is a linkage group selected from a direct bond, a divalent straight or branched alkyl group optionally containing one or more O atoms, divalent aryl group, divalent aralkyl group, or divalent monocycloalkyl or polycycloalkyl group optionally containing one or more O atoms;
X2 is hydrogen, halogen, or straight or branched alkyl chain optionally containing one or more O atoms;
R₈ is a straight or branched alkyl chain optionally containing one or more O atoms, a monocycloalkyl or polycycloalkyl group optionally containing one or more O atoms, or aryl;
X3 is hydrogen, straight or branched alkyl chain, halogen, cyano, or —C(═OO—R₅₀ where R₅₀ is selected from straight or branched alkyl chain optionally containing one or more O atoms or —O—R₅₁ where R₅₁ is hydrogen or straight or branched alkyl chain;
each of i and k are independently 0 or a positive integer;
j is 0 to 10;
m is 0 to 10;
and n is 0 to 10,
the straight or branched alkyl chain optionally containing one or more O atoms, straight or branched alkyl chain, straight or branched alkoxy chain, monocycloalkyl or polycycloalkyl group optionally containing one or more O atoms, monocycloalkyl- or polycycloalkylcarbonyl group, alkoxyalkyl, alkoxycarbonylalkyl, alkylcarbonyl, monocycloalkyl- or polycycloalkyloxycarbonylalkyl with the cycloalkyl ring optionally containing one or more O atoms, monocycloalkyl- or polycycloalkyloxyalkyl with the cycloalkyl ring optionally containing one or more O atoms, aralkyl, aryl, naphthyl, anthryl, 5-, 6-, or 7-membered saturated or unsaturated ring optionally containing one or more O atoms, or arylcarbonylmethyl group being unsubstituted or substituted by one or more groups selected from the group consisting of Z, halogen, alkyl, C₁₈ perfluoroalkyl, monocycloalkyl or polycycloalkyl, OR₂₀, alkoxy, C₃₋₂₀ cyclic alkoxy, dialkylamino, dicyclic dialkylamino, hydroxyl, cyano, nitro, tresyl, oxo, aryl, aralkyl, oxygen atom, CF₃SO₃, aryloxy, arylthio, and groups of formulae (II) to (VI):

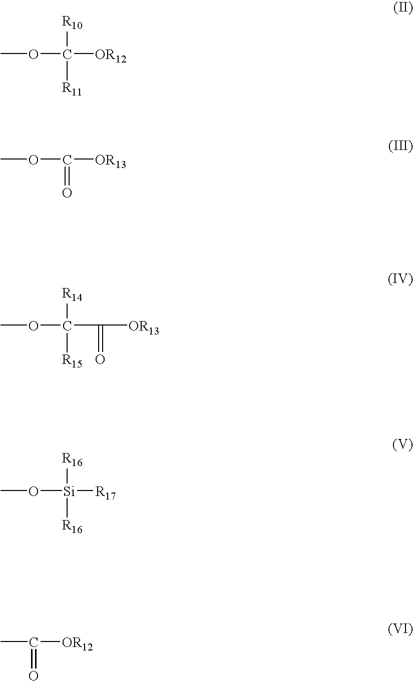

wherein R₁₀ and R₁₁ each independently represent a hydrogen atom, a straight or branched alkyl chain optionally containing one or more O atoms, or a monocycloalkyl or polycycloalkyl group optionally containing one or more O atoms, or R₁₀ and R₁₁ together can represent an alkylene group to form a five- or six-membered ring;
R₁₂ represents a straight or branched alkyl chain optionally containing one or more O atoms, a monocycloalkyl or polycycloalkyl group optionally containing one or more O atoms, or aralkyl, or R₁₀ and R₁₂ together represent an alkylene group which forms a five- or six-membered ring together with the interposing —C—O— group, the carbon atom in the ring being optionally substituted by an oxygen atom;
R₁₃ represents a straight or branched alkyl chain optionally containing one or more O atoms or a monocycloalkyl or polycycloalkyl group optionally containing one or more O atoms;
R₁₄ and R₁₅ each independently represent a hydrogen atom, a straight or branched alkyl chain optionally containing one or more O atoms or a monocycloalkyl or polycycloalkyl group optionally containing one or more O atoms;
R₁₆ represents a straight or branched alkyl chain optionally containing one or more O atoms, a monocycloalkyl or polycycloalkyl group optionally containing one or more O atoms, aryl, or aralkyl; and
R₁₇ represents straight or branched alkyl chain optionally containing one or more O atoms, a monocycloalkyl or polycycloalkyl group optionally containing one or more O atoms, aryl, aralkyl, the group —Si(R₁₆)₂R₁₇, or the group —O—Si(R₁₆)₂R₁₇, the straight or branched alkyl chain optionally containing one or more O atoms, monocycloalkyl or polycycloalkyl group optionally containing one or more O atoms, aryl, and aralkyl being unsubstituted or substituted as above;
Xi1 is an anion of the formula

Q-R₅₀₀—SO₃⁻

where Q is selected from ⁻O₃S and ⁻O₂C;
R₅₀₀ is a group selected from linear or branched alkyl, cycloalkyl, aryl, or combinations thereof, optionally containing a catenary O, S or N, where the alkyl, cycloalkyl, and aryl groups are unsubstituted or substituted by one or more groups selected from the group consisting of halogen, unsubstituted or substituted alkyl, unsubstituted or substituted C₁₈ perfluoroalkyl, hydroxyl, cyano, sulfate, and nitro; and
(ii) a compound of formula

Ai Xi2,

where Ai is an organic onium cation as previously defined and Xi2 is an anion.

Examples of anion Xi2 include those selected from CF₃SO₃⁻, CHF₂SO₃⁻, CH₃SO₃⁻, CCl₃SO₃⁻, C₂F₅SO₃⁻, C₂HF₄SO₃⁻, C₄F₉SO₃⁻, camphor sulfonate, perfluorooctane sulfonate, benzene sulfonate, pentafluorobenzene sulfonate, toluene sulfonate, perfluorotoluene sulfonate, (Rf1SO₂)₃C⁻ and (Rf1SO₂)₂N⁻, wherein each Rf1 is independently selected from the group consisting of highly fluorinated or perfluorinated alkyl or fluorinated aryl radicals and may be cyclic, when a combination of any two Rf1 groups are linked to form a bridge, further, the Rf1 alkyl chains contain from 1-20 carbon atoms and may be straight, branched, or cyclic, such that divalent oxygen, trivalent nitrogen or hexavalent sulfur may interrupt the skeletal chain, further when Rf1 contains a cyclic structure, such structure has 5 or 6 ring members, optionally, 1 or 2 of which are heteroatoms, and Rg-O—Rf2-SO₃⁻, where Rf2 is selected from the group consisting of linear or branched (CF₂)ⱼ where j is an integer from 4 to 10 and C₁-C₁₂ cycloperfluoroalkyl divalent radical which is optionally perfluoroC₁₋₁₀alkyl substituted, Rg is selected from the group consisting of C₁-C₂₀ linear, branched, monocycloalkyl or polycycloalkyl, C₁-C₂₀ linear, branched, monocycloalkenyl or polycycloalkenyl, aryl, and aralkyl, the alkyl, alkenyl, aralkyl and aryl groups being unsubstituted, substituted, optionally containing one or more catenary oxygen atoms, partially fluorinated or perfluorinated. Further examples include those selected from (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)₂(C₄F₉SO₂)C⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻ (SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃,

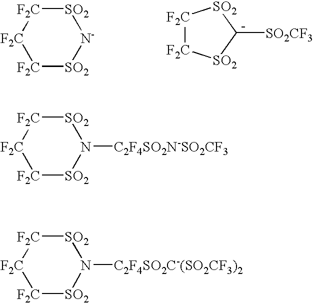

CF₃CHFO(CF₂)₄SO₃⁻, CF₃CH₂O(CF₂)₄SO₃⁻, CH₃CH₂O(CF₂)₄SO₃⁻, CH₃CH₂CH₂O(CF₂)₄SO₃⁻, CH₃O(CF₂)₄SO₃⁻, C₂H₅O(CF₂)₄SO₃⁻, C₄H₉O(CF₂)₄SO₃⁻, C₆H₅CH₂O(CF₂)₄SO₃⁻, C₂H₅OCF₂CF(CF₃)SO₃⁻, CH₂═CHCH₂O(CF₂)₄SO₃⁻, CH₃OCF₂CF(CF₃)SO₃⁻, C₄H₉OCF₂CF(CF₃)SO₃⁻, C₈H₁₇O(CF₂)₂SO₃⁻, and C₄H₉O(CF₂)₂SO₃⁻.

Further examples of the photoacid generators useful in the composition include those from the group bis(4-t-butylphenyl)iodonium triphenyl sulfonium perfluorobutane-1,4-disulfonate, bis(4-t-butylphenyl)iodonium triphenyl sulfonium perfluoropropane-1,3-disulfonate, bis(4-t-butylphenyl)iodonium triphenyl sulfonium perfluoropropane-1-carboxylate-3-sulfonate, bis(4-t-butylphenyl) iodonium triphenyl sulfonium perfluorobutane-1-carboxylate-4-sulfonate, bis(4-t-butylphenyl)iodonium triphenyl sulfonium perfluoromethane disulfonate, bis(4-t-butylphenyl)iodonium triphenyl sulfonium methane disulfonate, bis(4-t-butylphenyl)iodonium triphenyl sulfonium perfluoroethane disulfonate, bis(4-t-butylphenyl)iodonium triphenyl sulfonium ethane disulfonate, bis(triphenyl sulfonium)perfluorobutane-1,4-disulfonate, bis(triphenyl sulfonium) perfluoropropane-1,3-disulfonate, bis(benzoyltetramethylenesulfonium) perfluoropropane-1,3-disulfonate, bis(benzoyltetramethylenesulfonium) perfluorobutane-1,4-disulfonate, bis(tris(4-t-butylphenyl)sulfonium) perfluorobutane-1,4-disulfonate, bis(tris(4-t-butylphenyl)sulfonium) perfluoropropane-1,3-disulfonate, bis(4-t-butylphenyldiphenyl sulfonium) perfluorobutane-1,4-disulfonate, bis(4-t-butylphenyldiphenyl sulfonium) perfluoropropane-1,3-disulfonate, bis(triphenyl sulfonium)perfluoropropane-1-carboxylate-3-sulfonate, bis(triphenyl sulfonium)perfluorobutane-1-carboxylate-4-sulfonate, bis(benzoyltetramethylenesulfonium)perfluoropropane-1-carboxylate-3-sulfonate, bis(benzoyltetramethylenesulfonium)perfluorobutane-1-carboxylate-4-sulfonate, bis(tris(4-t-butyl phenyl)sulfonium)perfluoropropane-1-carboxylate-3-sulfonate, bis(tris(4-t-butyl phenyl)sulfonium)perfluorobutane-1-carboxylate-4-sulfonate, bis(4-t-butylphenyl diphenyl sulfonium) perfluoropropane-1-carboxylate-3-sulfonate, bis(4-t-butylphenyl diphenyl sulfonium)perfluorobutane-1-carboxylate-4-sulfonate, bis(4-t-butylphenyl iodonium)methane disulfonate, bis(triphenyl sulfonium)methane disulfonate, bis(4-t-butylphenyl iodonium)perfluoromethane disulfonate, bis(triphenyl sulfonium)perfluoromethane disulfonate, bis(benzoyltetramethylenesulfonium) perfluoromethane disulfonate, bis(benzoyl-tetramethylenesulfonium)methane disulfonate, bis(tris(4-t-butyl phenyl)sulfonium)perfluoromethane disulfonate, bis(tris(4-t-butyl phenyl)sulfonium)methane disulfonate, bis(4-t-butylphenyl diphenylsulfonium)perfluoromethane disulfonate, bis(4-t-butylphenyl diphenylsulfonium)methane disulfonate, bis(4-octyloxyphenyl)iodonium perfluorobutane-1,4-disulfonate, bis(4-octyloxyphenyl)iodonium ethane disulfonate, bis(4-octyloxyphenyl)iodonium perfluoroethane disulfonate, bis(4-octyloxyphenyl)iodonium perfluoropropane-1,3-disulfonate, bis(4-octyloxyphenyl) iodonium perfluoropropane-1-carboxylate-3-sulfonate, bis(4-octyloxyphenyl) iodonium perfluorobutane-1-carboxylate-4-sulfonate, bis(4-octyloxyphenyl) iodonium methane disulfonate, bis(4-octyloxyphenyl)iodonium perfluoromethane disulfonate, bis(4-octyloxyphenyl)phenyl sulfonium perfluorobutane-1,4-disulfonate, bis(4-octyloxyphenyl)phenyl sulfonium ethane disulfonate, bis(4-octyloxyphenyl)phenyl sulfonium perfluoroethane disulfonate, bis(4-octyloxyphenyl)phenyl sulfonium perfluoropropane-1,3-disulfonate, bis(4-octyloxyphenyl)phenyl sulfonium perfluoropropane-1-carboxylate-3-sulfonate, bis(4-octyloxyphenyl)phenyl sulfonium perfluorobutane-1-carboxylate-4-sulfonate, bis(4-octyloxyphenyl)phenyl sulfonium methane disulfonate, bis(4-octyloxyphenyl)phenyl sulfonium perfluoromethane disulfonate, bis[bis[4-pentafluorobenzenesulfonyloxy-phenyl]phenylsulfonium]perfluorobutane-1,4-disulfonate, bis[bis[4-pentafluoro-benzene-sulfonyloxyphenyl]phenylsulfonium]ethane disulfonate, bis[bis[4-pentafluorobenzenesulfonyloxyphenyl]phenylsulfonium]perfluoroethane disulfonate, bis[bis[4-pentafluorobenzenesulfonyloxyphenyl]phenylsulfonium]perfluoropropane-1,3-disulfonate, bis[bis[4-pentafluorobenzenesulfonyloxyphenyl]phenylsulfonium]perfluoropropane-1-carboxylate-3-sulfonate, bis[bis[4-pentafluorobenzenesulfonyloxy-phenyl]phenylsulfonium]perfluorobutane-1-carboxylate-4-sulfonate, bis[bis[4-pentafluorobenzenesulfonyloxyphenyl]phenylsulfonium]methane disulfonate, bis[bis[4-pentafluorobenzenesulfonyloxyphenyl]phenylsulfonium]perfluoromethane disulfonate, bis[bis[4-(3,5-di(trifluoromethyl)benzenesulfonyloxy)-phenyl]phenylsulfonium]perfluorobutane-1,4-disulfonate, bis[bis[4-(3,5-di(trifluoromethyl)-benzenesulfonyloxy)phenyl]phenylsulfonium]ethane disulfonate, bis[bis[4-(3,5-di(trifluoromethyl)benzenesulfonyloxy)phenyl]phenylsulfonium]perfluoroethane disulfonate, bis[bis[4-(3,5-di(trifluoromethyl)benzenesulfonyloxy)phenyl]phenylsulfonium]perfluoropropane-1,3-disulfonate, bis[bis[4-(3,5-di(trifluoromethyl)-benzenesulfonyloxy)phenyl]phenylsulfonium]perfluoropropane-1-carboxylate-3-sulfonate, bis[bis[4-(3,5-di(trifluoromethyl)benzenesulfonyloxy)-phenyl]phenylsulfonium]perfluorobutane-1-carboxylate-4-sulfonate, bis[bis[4-(3,5-di(trifluoromethyl)benzenesulfonyloxy)phenyl]phenylsulfonium]methane disulfonate, bis(4-t-butylphenyl iodonium)ethane disulfonate, bis(4-t-butylphenyl iodonium)perfluoroethane disulfonate, bis(triphenyl sulfonium)ethane disulfonate, bis(triphenyl sulfonium)perfluoroethane disulfonate, bis(benzoyltetramethylene-sulfonium)perfluoroethane disulfonate, bis(benzoyltetramethylenesulfonium)ethane disulfonate, bis(tris(4-t-butyl phenyl) sulfonium)perfluoroethane disulfonate, bis(tris(4-t-butyl phenyl)sulfonium) ethane disulfonate, bis(4-t-butylphenyl diphenyl-sulfonium)perfluoroethane disulfonate, bis(4-t-butylphenyl diphenylsulfonium)ethane disulfonate, bis[bis[2-methyladamantylacetyloxymethoxyphenyl]phenyl-sulfonium]perfluorobutane-1,4-disulfonate, bis[bis[2-methyladamantylacetyl-oxymethoxyphenyl]phenylsulfonium]ethane disulfonate, bis[bis[2-methyladamantylacetyl-oxymethoxyphenyl]phenylsulfonium]perfluoroethane disulfonate, bis[bis[2-methyladamantylacetyloxymethoxyphenyl]phenylsulfonium]perfluoro-propane-1,3-disulfonate, bis[bis[2-methyladamantylacetyloxymethoxyphenyl]phenylsulfonium]perfluoropropane-1-carboxylate-3-sulfonate, bis[bis[2-methyl-adamantylacetyloxymethoxyphenyl]phenylsulfonium]perfluorobutane-1-carboxylate-4-sulfonate, bis[bis[2-methyladamantylacetyloxymethoxyphenyl]phenylsulfonium]methane disulfonate, bis[bis[2-methyladamantylacetyloxy-methoxyphenyl]phenylsulfonium]perfluoromethane disulfonate, bis[bis[4,4-bis(trifluoromethyl)-3-oxatricyclo[4.2.1.0^{2,5}]-nonylmethoxyphenyl]phenyl sulfonium]perfluorobutane-1,4-disulfonate, bis[bis[4,4-bis(trifluoromethyl)-3-oxatricyclo-[4.2.1.0^{2,5}]-nonylmethoxy-phenyl]phenyl sulfonium]ethane disulfonate, bis[bis[4,4-bis(trifluoromethyl)-3-oxatricyclo[4.2.1.0^{2,5}]-nonylmethoxyphenyl]phenyl sulfonium]-perfluoroethane disulfonate, bis[bis[4,4-bis(trifluoromethyl)-3-oxatricyclo[4.2.1.0^{2,5}]-nonylmethoxy-phenyl]phenyl sulfonium]perfluoropropane-1,3-disulfonate, bis[bis[4,4-bis(trifluoro-methyl)-3-oxatricyclo[4.2.1.0^{2,5}]-nonylmethoxyphenyl]phenyl sulfonium]-perfluoropropane-1-carboxylate-3-sulfonate, bis[bis[4,4-bis(trifluoro-methyl)-3-oxatricyclo[4.2.1.0^{2,5}]-nonylmethoxyphenyl]phenyl sulfonium]perfluoro-butane-1-carboxylate-4-sulfonate, bis[bis[4,4-bis(trifluoromethyl)-3-oxatricyclo-[4.2.1.0^{2,5}]-nonylmethoxyphenyl]phenyl sulfonium]methane disulfonate, bis[bis[4,4-bis(trifluoromethyl)-3-oxatricyclo[4.2.1.0^{2,5}]-nonylmethoxyphenyl]phenyl sulfonium]perfluoromethane disulfonate, bis(4-t-butylphenyl)iodonium bis-perfluoroethane sulfonimide, diphenyliodonium trifluoromethane sulfonate, diphenyliodonium nonafluorobutane sulfonate, triphenylsulfonium trifluromethane sulfonate, triphenylsulfonium nonafluorobutane sulfonate, 4-(1-butoxyphenyl)diphenylsulfonium bis-(perfluorobutanesulfonyl)imide, 4-(1-butoxyphenyl)diphenylsulfonium bis-(perfluoroethanesulfonyl)imide, 2,4,6-trimethylphenyldiphenylsulfonium bis-perfluorobutanesulfonyl)imide, 2,4,6-trimethylphenyldiphenylsulfonium bis-(perfluoroethanesulfonyl)imide, toluenediphenylsulfonium bis-(perfluorobutanesulfonyl)imide, toluenediphenylsulfonium bis-(perfluoroethanesulfonyl)imide, toluenediphenylsulfonium-(trifluoromethyl perfluorobutylsulfonyl)imide, tris-(tert-butylphenyl)sulfonium-(trifluoromethyl perfluorobutylsulfonyl)imide, tris-(tert-butylphenyl)sulfonium bis-(perfluorobutanesulfonyl)imide, and tris-(tert-butylphenyl)sulfonium-bis-(trifluoromethanesulfonyl)imide.

The term alkyl as used herein means a straight or branched chain hydrocarbon. Representative examples of alkyl include, but are not limited to, methyl, ethyl, n-propyl, iso-propyl, n-butyl, sec-butyl, iso-butyl, tert-butyl, n-pentyl, isopentyl, neopentyl, n-hexyl, 3-methylhexyl, 2,2-dimethylpentyl, 2,3-dimethylpentyl, n-heptyl, n-octyl, n-nonyl, and n-decyl.

Alkylene refers to divalent alkyl radicals, which can be linear or branched, such as, for example, methylene, ethylene, propylene, butylene or the like.

By the term aryl is meant a radical derived from an aromatic hydrocarbon by the elimination of one atom of hydrogen and can be substituted or unsubstituted. The aromatic hydrocarbon can be mononuclear or polynuclear. Examples of aryl of the mononuclear type include phenyl, tolyl, xylyl, mesityl, cumenyl, and the like. Examples of aryl of the polynuclear type include naphthyl, anthryl, phenanthryl, and the like. The aryl group can be unsubstituted or substituted as provided for hereinabove.

The term alkoxy refers to a group of alkyl-O—, where alkyl is defined herein. Representative examples of alkoxy include, but are not limited to, methoxy, ethoxy, propoxy, 2-propoxy, butoxy, tert-butoxy, pentyloxy, and hexyloxy.

The term aryloxy refers to a group of aryl-O—, where aryl is defined herein.

By the term aralkyl is meant an alkyl group containing an aryl group. It is a hydrocarbon group having both aromatic and aliphatic structures, that is, a hydrocarbon group in which a lower alkyl hydrogen atom is substituted by a mononuclear or polynuclear aryl group. Examples of aralkyl groups include, without limitation, benzyl, 2-phenyl-ethyl, 3-phenyl-propyl, 4-phenyl-butyl, 5-phenyl-pentyl, 4-phenylcyclohexyl, 4-benzylcyclohexyl, 4-phenylcyclohexylmethyl, 4-benzylcyclohexylmethyl, naphthylmethyl, and the like.

The term monocycloalkyl as used herein, refers to an optionally substituted, saturated or partially unsaturated monocycloalkyl ring system, where if the ring is partially unsaturated, it is then a monocycloalkenyl group. The term polycycloalkyl as used herein refers to an optionally substituted, saturated or partially unsaturated polycycloalkyl ring system containing two or more rings, where if the ring is partially unsaturated, it is then a polycycloalkenyl group. Examples of monocycloalkyl or polycycloalkyl groups optionally containing one or more O atoms are well know to those skilled in the art and include, for example, cyclopropyl, cyclobutyl, cyclopentyl, cycloheptyl, cyclohexyl, 2-methyl-2-norbornyl, 2-ethyl-2-norbornyl, 2-methyl-2-isobornyl, 2-ethyl-2-isobornyl, 2-methyl-2-adamantyl, 2-ethyl-2-adamantyl, 1-adamantyl-1-methylethyl, adamantyl, tricyclodecyl, 3-oxatricyclo[4.2.1.0^{2,5}]nonyl, tetracyclododecanyl, tetracyclo [5.2.2.0.0]undecanyl, bornyl, isobornyl norbornyl lactone, adamantyl lactone and the like.

The term alkoxycarbonylalkyl embraces alkyl radicals substituted with an alkoxycarbonyl radical as defined herein. Examples of alkoxycarbonylalkyl radicals include methoxycarbonylmethyl [CH₃O—C(═O)—CH₂—], ethoxycarbonyl methyl [CH₃CH₂O—C(═O)—CH₂—], methoxycarbonylethyl [CH₃O—C(═O)—CH₂CH₂—], and ethoxycarbonylethyl [CH₃CH₂O—C(═O)—CH₂CH₂—].

The term alkylcarbonyl as used herein means an alkyl group, as defined herein, appended to the parent molecular moiety through a carbonyl group, as defined herein, which can be generically represented as alkyl-C(O)—. Representative examples of alkylcarbonyl include, but are not limited to acetyl (methyl carbonyl), butyryl(propylcarbonyl), octanoyl(heptylcarbonyl), dodecanoyl (undecylcarbonyl), and the like.

Alkoxycarbonyl means alkyl-O—C(O)—, wherein alkyl is as previously described. Non-limiting examples include methoxycarbonyl [CH₃O—C(O)—] and the ethoxycarbonyl [CH₃CH₂O—C(O)—], benzyloxycarbonyl [C₆H₅CH₂O—C(O)—] and the like.

Alkoxyalkyl means that a terminal alkyl group is linked through an ether oxygen atom to an alkyl moiety, which can be generically represented as alkyl-O-alkyl wherein the alkyl groups can be linear or branched. Examples of alkoxyalkyl include, but are not limited to, methoxypropyl, methoxybutyl, ethoxypropyl, methoxymethyl

Monocycloalkyl- or polycycloalkyloxycarbonylalkyl means that a terminal monocycloalkyl or polycycloalkyl group is linked through —O—C(═O)— to an alkyl moiety, generically represented as monocycloalkyl- or polycycloalkyl-O—C(═O)-alkyl.

Monocycloalkyl- or polycycloalkyloxyalkyl means that a terminal monocycloalkyl or polycycloalkyl group is linked through an ether oxygen atom to an alkyl moiety, which can be generically represented as monocycloalkyl- or polycycloalkyl-O-alkyl.

Monocyclofluoroalkyl- or polycyclofluoroalkyl means a monocyclalkyl- or polycycloalkyl group substituted with one or more fluorine atoms.

Examples of substituents which can be placed on the alkyl, aryl, aralkyl, and the other groups mentioned above, including those on the groups defined as R₃₀, R₃₁, R₃₂, R₃₃, R₅, R₄₀, R₄₁, and R₄₂, include, but are not limited to, halogen, hydroxyl, sulfate, nitro, perfluoroalkyl, oxo, alkyl, alkoxy, aryl, and the like, etc.

The solid components of the present invention are dissolved in an organic solvent. The amount of solids in the solvent or mixture of solvents ranges from about 1 weight % to about 50 weight %. The polymer may be in the range of 5 weight % to 90 weight % of the solids and the photoacid generators may be in the range of 0.4 weight % to about 50 weight % of the solids. Suitable solvents for such photoresists may include for example ketones such as acetone, methyl ethyl ketone, methyl isobutyl ketone, cyclohexanone, isophorone, methyl isoamyl ketone, 2-heptanone 4-hydroxy, and 4-methyl 2-pentanone; C₁ to C₁₀ aliphatic alcohols such as methanol, ethanol, and propanol; aromatic group containing—alcohols such as benzyl alcohol; cyclic carbonates such as ethylene carbonate and propylene carbonate; aliphatic or aromatic hydrocarbons (for example, hexane, toluene, xylene, etc and the like); cyclic ethers, such as dioxane and tetrahydrofuran; ethylene glycol; propylene glycol; hexylene glycol; ethylene glycol monoalkylethers such as ethylene glycol monomethylether, ethylene glycol monoethylether; ethylene glycol alkylether acetates such as methylcellosolve acetate and ethylcellosolve acetate; ethylene glycol dialkylethers such as ethylene glycol dimethylether, ethylene glycol diethylether, ethylene glycol methylethylether, diethylene glycol monoalkylethers such as diethylene glycol monomethylether, diethylene glycol monoethylether, and diethylene glycol dimethylether; propylene glycol monoalkylethers such as propylene glycol methylether, propylene glycol ethylether, propylene glycol propylether, and propylene glycol butylether; propylene glycol alkyletheracetates such as propylene glycol methylether acetate, propylene glycol ethylether acetate, propylene glycol propylether acetate, and propylene glycol butylether acetate; propylene glycol alkyletherpropionates such as propylene glycol methyletherpropionate, propylene glycol ethyletherpropionate, propylene glycol propyletherpropionate, and propylene glycol butyletherpropionate; 2-methoxyethyl ether (diglyme); solvents that have both ether and hydroxy moieties such as methoxy butanol, ethoxy butanol, methoxy propanol, and ethoxy propanol; esters such as methyl acetate, ethyl acetate, propyl acetate, and butyl acetate methyl-pyruvate, ethyl pyruvate; ethyl 2-hydroxy propionate, methyl 2-hydroxy 2-methyl propionate, ethyl 2-hydroxy 2-methyl propionate, methyl hydroxy acetate, ethyl hydroxy acetate, butyl hydroxy acetate, methyl lactate, ethyl lactate, propyl lactate, butyl lactate, methyl 3-hydroxy propionate, ethyl 3-hydroxy propionate, propyl 3-hydroxy propionate, butyl 3-hydroxy propionate, methyl 2-hydroxy 3-methyl butanoic acid, methyl methoxy acetate, ethyl methoxy acetate, propyl methoxy acetate, butyl methoxy acetate, methyl ethoxy acetate, ethyl ethoxy acetate, propyl ethoxy acetate, butyl ethoxy acetate, methyl propoxy acetate, ethyl propoxy acetate, propyl propoxy acetate, butyl propoxy acetate, methyl butoxy acetate, ethyl butoxy acetate, propyl butoxy acetate, butyl butoxy acetate, methyl 2-methoxy propionate, ethyl 2-methoxy propionate, propyl 2-methoxy propionate, butyl 2-methoxy propionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, and butyl 3-butoxypropionate; oxyisobutyric acid esters, for example, methyl-2-hydroxyisobutyrate, methyl α-methoxyisobutyrate, ethyl methoxyisobutyrate, methyl α-ethoxyisobutyrate, ethyl α-ethoxyisobutyrate, methyl β-methoxyisobutyrate, ethyl β-methoxyisobutyrate, methyl β-ethoxyisobutyrate, ethyl β-ethoxyisobutyrate, methyl β-isopropoxyisobutyrate, ethyl α-isopropoxyisobutyrate, isopropyl β-isopropoxyisobutyrate, butyl α-isopropoxyisobutyrate, methyl α-butoxyisobutyrate, ethyl α-butoxyisobutyrate, butyl α-butoxyisobutyrate, methyl α-hydroxyisobutyrate, ethyl α-hydroxyisobutyrate, isopropyl α-hydroxyisobutyrate, and butyl α-hydroxyisobutyrate; solvents that have both ether and hydroxy moieties such as methoxy butanol, ethoxy butanol, methoxy propanol, and ethoxy propanol; and other solvents such as dibasic esters, and gamma-butyrolactone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

Various other additives such as colorants, non-actinic dyes, anti-striation agents, plasticizers, adhesion promoters, dissolution inhibitors, coating aids, photospeed enhancers, additional photoacid generators, and solubility enhancers (for example, certain small levels of solvents not used as part of the main solvent (examples of which include glycol ethers and glycol ether acetates, valerolactone, ketones, lactones, and the like), and surfactants may be added to the photoresist composition before the solution is coated onto a substrate. Surfactants that improve film thickness uniformity, such as fluorinated surfactants, can be added to the photoresist solution. A sensitizer that transfers energy from a particular range of wavelengths to a different exposure wavelength may also be added to the photoresist composition. Often bases are also added to the photoresist to prevent t-tops or bridging at the surface of the photoresist image. Examples of bases are amines, ammonium hydroxide, and photosensitive bases. Particularly preferred bases are trioctylamine, diethanolamine and tetrabutylammonium hydroxide.

The prepared photoresist composition solution can be applied to a substrate by any conventional method used in the photoresist art, including dipping, spraying, and spin coating. When spin coating, for example, the photoresist solution can be adjusted with respect to the percentage of solids content, in order to provide coating of the desired thickness, given the type of spinning equipment utilized and the amount of time allowed for the spinning process. Suitable substrates include silicon, aluminum, polymeric resins, silicon dioxide, doped silicon dioxide, silicon nitride, tantalum, copper, polysilicon, ceramics, aluminum/copper mixtures; gallium arsenide and other such Group III/V compounds. The photoresist may also be coated over antireflective coatings.

The photoresist coatings produced by the described procedure are particularly suitable for application to silicon/silicon dioxide wafers, such as are utilized in the production of microprocessors and other miniaturized integrated circuit components. An aluminum/aluminum oxide wafer can also be used. The substrate may also comprise various polymeric resins, especially transparent polymers such as polyesters.

The photoresist composition solution is then coated onto the substrate, and the substrate is treated (baked) at a temperature from about 70° C. to about 150° C. for from about 30 seconds to about 180 seconds on a hot plate or for from about 15 to about 90 minutes in a convection oven. This temperature treatment is selected in order to reduce the concentration of residual solvents in the photoresist, while not causing substantial thermal degradation of the solid components. In general, one desires to minimize the concentration of solvents and this first temperature. Treatment (baking) is conducted until substantially all of the solvents have evaporated and a thin coating of photoresist composition, on the order of half a micron (micrometer) in thickness, remains on the substrate. In a preferred embodiment the temperature is from about 95° C. to about 120° C. The treatment is conducted until the rate of change of solvent removal becomes relatively insignificant. The film thickness, temperature and time selection depends on the photoresist properties desired by the user, as well as the equipment used and commercially desired coating times. The coated substrate can then be imagewise exposed to actinic radiation, e.g., ultraviolet radiation, at a wavelength of from about 100 nm (nanometers) to about 300 nm, x-ray, electron beam, ion beam or laser radiation, in any desired pattern, produced by use of suitable masks, negatives, stencils, templates, etc.

The photoresist is then subjected to a post exposure second baking or heat treatment before development. The heating temperatures may range from about 90° C. to about 150° C., more preferably from about 100° C. to about 130° C. The heating may be conducted for from about 30 seconds to about 2 minutes, more preferably from about 60 seconds to about 90 seconds on a hot plate or about 30 to about 45 minutes by convection oven.

The exposed photoresist-coated substrates are developed to remove the image-wise exposed areas by immersion in a developing solution or developed by spray development process. The solution is preferably agitated, for example, by nitrogen burst agitation. The substrates are allowed to remain in the developer until all, or substantially all, of the photoresist coating has dissolved from the exposed areas. Developers include aqueous solutions of ammonium or alkali metal hydroxides. One preferred developer is an aqueous solution of tetramethyl ammonium hydroxide. After removal of the coated wafers from the developing solution, one may conduct an optional post-development heat treatment or bake to increase the coating's adhesion and chemical resistance to etching conditions and other substances. The post-development heat treatment can comprise the oven baking of the coating and substrate below the coating's softening point or UV hardening process. In industrial applications, particularly in the manufacture of microcircuitry units on silicon/silicon dioxide-type substrates, the developed substrates may be treated with a buffered, hydrofluoric acid base etching solution or dry etching. Prior to dry etching the photoresist may be treated to electron beam curing in order to increase the dry-etch resistance of the photoresist.

The invention further provides a method for producing a semiconductor device by producing a photo-image on a substrate by coating a suitable substrate with a photoresist composition. The subject process comprises coating a suitable substrate with a photoresist composition and heat treating the coated substrate until substantially all of the photoresist solvent is removed; image-wise exposing the composition and removing the image-wise exposed areas of such composition with a suitable developer.

The following examples provide illustrations of the methods of producing and utilizing the present invention. These examples are not intended, however, to limit or restrict the scope of the invention in any way and should not be construed as providing conditions, parameters or values which must be utilized exclusively in order to practice the present invention. Unless otherwise specified, all parts and percents are by weight.

The additional photoacid generators of formula (Ai)₂ Xi1 can be made in accordance with the procedures set forth in U.S. patent application Ser. Nos. 11/179,886, filed Jul. 12, 2005, and Ser. No. 11/355,762, filed Feb. 16, 2006, the contents of which are hereby incorporated herein by reference. Other examples are found in U.S. patent application Ser. No. 11/355,400, filed Feb. 16, 2006, U.S. Published patent application No. 2004-0229155, and U.S. Published patent application No. 2005-0271974, U.S. Pat. No. 5,837,420, U.S. Pat. No. 6,111,143, and U.S. Pat. No. 6,358,665, the contents of which are hereby incorporated herein by reference. Those additional photoacid generators of formula Ai Xi2 are well known to those skilled in the art, for example, those known from U.S. patent application No. 20030235782 and U.S. patent application No. 20050271974, the contents of which are hereby incorporated herein by reference.

### POLYMER SYNTHESIS EXAMPLE 1 Poly(EDiMA/HAdA/α-GBLMA)

4.55 g of 2-ethyldiamantylmethacrylate (EDiMA), 3.37 g of HAdA, 3.44 g of α-GBLMA (mol percent feed ratio of 30/30/40), and 1.14 g of Perkadox-16 were dissolved in 37.5 g of tetrahydrofuran (THF). The temperature was raised to 70° C. and the reactants were mixed for 5 hours. The polymer was precipitated in methanol (MeOH) twice and hexane once. The yield of the polymer was 55%. The weight average molecular weight (M_{W}) was 8408, the polydispersity (PD) was 1.46, and the glass transition temperature (Tg) was 162° C. measured on a TA Instruments differential scanning calorimeter (DSC).

### POLYMER SYNTHESIS EXAMPLE 2 Poly(EDiMA/HAdA/β-GBLMA)

8.19 g of 2-ethyldiamantylmethacrylate (EDiMA), 6.07 g of HAdA, 12.39 g of β-GBLMA (mol percent feed ratio of 30/30/40), and 2.05 g of Perkadox-16 were dissolved in 61.3 g of THF. The temperature was raised to 70° C. and the reactants were mixed for 5 hours. The polymer was precipitated in MeOH twice and hexane once. The yield of the polymer was 37%. The weight average molecular weight (M_{W}) was 7593, the polydispersity (PD) was 1.86, and the glass transition temperature (Tg) was 155° C. measured on DSC.

### POLYMER SYNTHESIS EXAMPLE 3 Poly(EDiMA/HAdA/α-GBLMA)

6.35 g of 2-ethyldiamantylmethacrylate (EDiMA), 2.61 g of HAdA, 2.4 g of α-GBLMA (mol percent feed ratio of 45/25/30), and 1.14 g of Perkadox-16 were dissolved in 37.5 g of THF. The temperature was raised to 70° C. and the reactants were mixed for 5 hours. The polymer was precipitated in MeOH twice and hexane once. The yield of the polymer was 37%. The weight average molecular weight (M_{W}) was 7886, the polydispersity (PD) was 1.66, and the glass transition temperature (Tg) was 168° C. measured on DSC.

### POLYMER SYNTHESIS EXAMPLE 4 Poly(EDiMA/HAdA/α-GBLMA)

17.21 g of 2-ethyldiamantylmethacrylate (EDiMA), 9.56 g of HAdA, 7.32 g of α-GBLMA (mol percent feed ratio of 40/30/30), and 3.41 g of Perkadox-16 were dissolved in 112.50 g of THF. The temperature was raised to 70° C. and the reactants were mixed for 5 hours. The polymer was precipitated in MeOH twice and hexane once. The yield of the polymer was 41%. The weight average molecular weight (M_{W}) was 7405, the polydispersity (PD) was 1.46, and the glass transition temperature (Tg) was 130° C. measured on DSC.

### POLYMER SYNTHESIS EXAMPLE 5 Poly(EDiMA/HAdA/β-GBLMA)

13.34 g of 2-ethyldiamantylmethacrylate (EDiMA), 13.18 g of HAdA, 15.14 g of β-GBLMA (mol percent feed ratio of 30/40/30), and 3.41 g of Perkadox-16 were dissolved in 105 g of THF. The temperature was raised to 70° C. and the reactants were mixed for 5 hours. The polymer was precipitated in MeOH twice and hexane once. The yield of the polymer was 42%. The weight average molecular weight (M_{W}) was 10160, the polydispersity (PD) was 1.46, and the glass transition temperature (Tg) was 120° C. measured on DSC.

### POLYMER SYNTHESIS EXAMPLE 6 Poly(EDiMA/HAdA/α-GBLMA)

15.31 g of 2-ethyldiamantylmethacrylate (EDiMA), 13.34 g of HAdA, 7.44 g of α-GBLMA (mol percent feed ratio of 35/35/30), and 3.41 g of Perkadox-16 were dissolved in 113 g of THF. The temperature was raised to 70° C. and the reactants were mixed for 5 hours. The polymer was precipitated in MeOH twice and hexane once. The yield of the polymer was 45%. The weight average molecular weight (M_{W}) was 10160, the polydispersity (PD) was 1.46, and the glass transition temperature (Tg) was 130° C. measured on DSC.

### POLYMER SYNTHESIS EXAMPLE 7 Poly(EDiMA/HAdA/α-GBLA)

14.0 of 2-ethyldiamantylmethacrylate (EDiMA), 10.37 g of HAdA, 9.72 g of α-GBLA (mol percent feed ratio of 30/30/40), and 3.41 g of Perkadox-16 were dissolved in 113 g of THF. The temperature was raised to 70° C. and the reactants were mixed for 5 hours. The polymer was precipitated in MeOH twice and hexane once. The yield of the polymer was 35%. The weight average molecular weight (M_{W}) was 9913, the polydispersity (PD) was 1.57, and the glass transition temperature (Tg) was 113° C. measured on DSC.

### FORMULATION EXAMPLE 1

0.7876 g of the made in Polymer synthesis example 2, 0.0183 g of bis(p-tertbutyl phenyl)iodonium perfluoroethanesulfonylimide, 0.0210 g of bis(triphenylsulfonium) perfluorobutane-1,4-disulfonate, 0.0424 grams of bis(p-tertiarybutylphenyl)iodonium perfluorobutane-1,4-disulfonate, 0.0053 grams of N,N-diisopropylaniline, 0.0030 grams of non-ionic polymeric fluorochemical surfactant supplied by 3M Corporation were dissolved in 19.297 g of methyl-2-hydroxyisobutyrate (MHIB) and 4.74 g of propylene glycol monomethyl ether and 0.0838 g of gamma valerolactone. The solution was thoroughly mixed for complete dissolution and filtered using 0.2 um filter.

A silicon substrate coated with a bottom antireflective coating (B.A.R.C.) was prepared by spin coating the bottom anti-reflective coating solution (AZ® ArF-38, B.A.R.C. available from AZ Electronic Materials Corporation, Somerville, N.J.) onto the silicon substrate and baking at 225° C. for 90 sec. The B.A.R.C film thickness was 87 nm. The photoresist solution thus prepared was then coated on the B.A.R.C coated silicon substrate. The spin speed was adjusted such that the photoresist film thickness was 120 nm, soft baked at 100° C./60 s, exposed with Nikon 306D 0.85NA & dipole illumination using 6% half-tone mask. The exposed wafer was post exposure baked at 110° C./60 s, and developed using a 2.38 weight % aqueous solution of tetramethyl ammonium hydroxide for 30 sec. The line and space patterns were then measured on a AMAT CD SEM. The sensitivity to print 70 nm dense CD was 40 mJ, with a DoF of 0.35 μm and the average 3sigma LER/LWR values at +/−0.10 μm DoF was 5.0 and 7.44 nm, respectively.

### FORMULATION EXAMPLE 2

Using the polymer made in Polymer synthesis example 4, a formulation was made and processed exactly same way as described in Formulation Example 1. The resist had a sensitivity of 38 mJ to print 70 nm dense CD, with a DoF of 0.4 μm, and the average 3sigma LER/LWR values at +/−0.10 μm DoF was 5.4 and 8.1 nm, respectively.

### FORMULATION EXAMPLE 3

Using the polymer made in Polymer synthesis example 5, a formulation was made and processed exactly same way as described in Formulation Example 1. The resist had a sensitivity of 38 mJ to print 70 nm dense CD, with a DoF of 0.35 μm, and the average 3sigma LER/LWR values at +/−0.10 μm DoF was 5.48 and 8.1 nm, respectively.

### FORMULATION EXAMPLE 4

Using the polymer made in Polymer synthesis example 6, a formulation was made and processed exactly same way as described in Formulation Example 1. The resist had a sensitivity of 39 mJ to print 70 nm dense CD, with a DoF of 0.40 μm, and the average 3sigma LER/LWR values at +/−0.10 μm DoF was 5.01 and 7.4 nm, respectively.

### FORMULATION EXAMPLE 5

Using the polymer made in Polymer synthesis example 7, a formulation was made and processed exactly same way as described in Formulation Example 1. The resist had a sensitivity of 29 mJ to print 70 nm dense CD, with a DoF of 0.25 μm, and the average 3sigma LER/LWR values at +/−0.10 μm DoF was 7.34 and 11.72 nm, respectively.

### FORMULATION EXAMPLE 6

Using the polymer made in Polymer synthesis example 3, a formulation was made and processed exactly same way as described in Formulation Example 1. The film after coating and soft bake was hazy no patterns could be resolved.

The foregoing description of the invention illustrates and describes the present invention. Additionally, the disclosure shows and describes only certain embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. A polymer having the formula 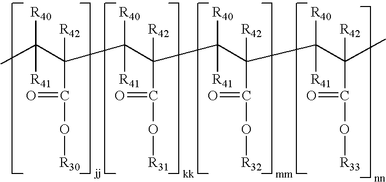
where
R₃₀ is selected from 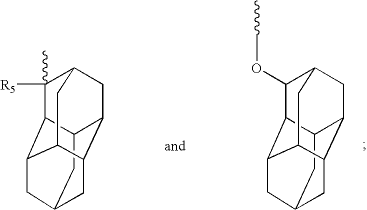
R₃₁ is a polycycloalkyl group substituted with one or more hydroxyl groups;
R₃₂ is an unsubstituted or substituted monocycloalkyl or polycycloalkyl lactone;
R₃₃ is selected from R₃₂, unsubstituted or substituted alkyl, unsubstituted or substituted monocylcoalkyl, and unsubstituted or substituted polycycloalkyl groups;
R₅ is selected from unsubstituted or substituted alkyl, unsubstituted or substituted alkoxy, unsubstituted or substituted monocylcoalkyl, and unsubstituted or substituted polycycloalkyl groups;
R₄₀, R₄₁, and R₄₂ are each selected from hydrogen and unsubstituted or substituted C₁₋₄ alkyl; and
jj is an integer from 1 to 60; kk is an integer ranging from 0 to 60; mm is an integer ranging from 0 to 60; and nn is an integer ranging from 0 to 60, where jj+kk+mm+nn=100.

2. The polymer of claim 1 wherein R₃₁ is selected from

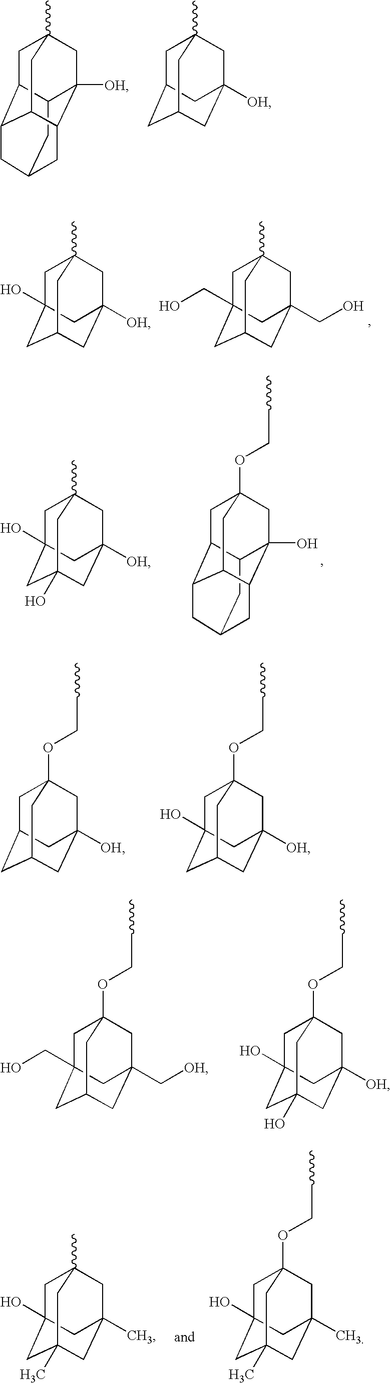

3. The polymer of claim 1, wherein R₃₂ is selected from

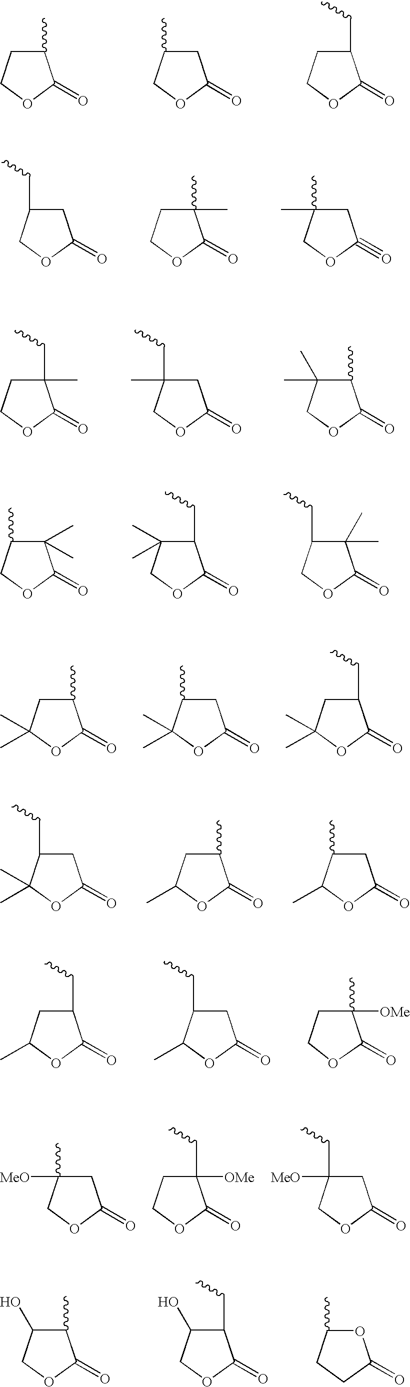

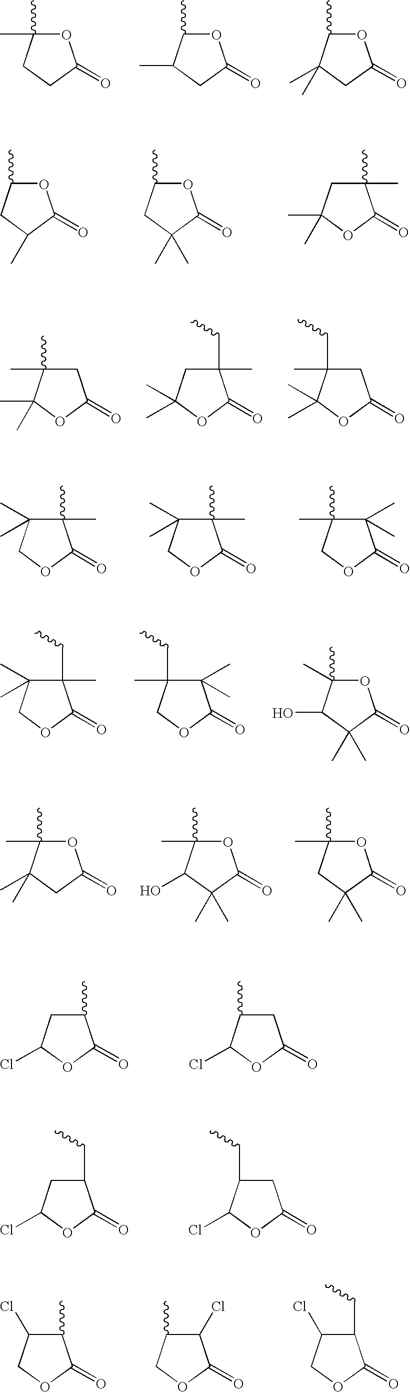

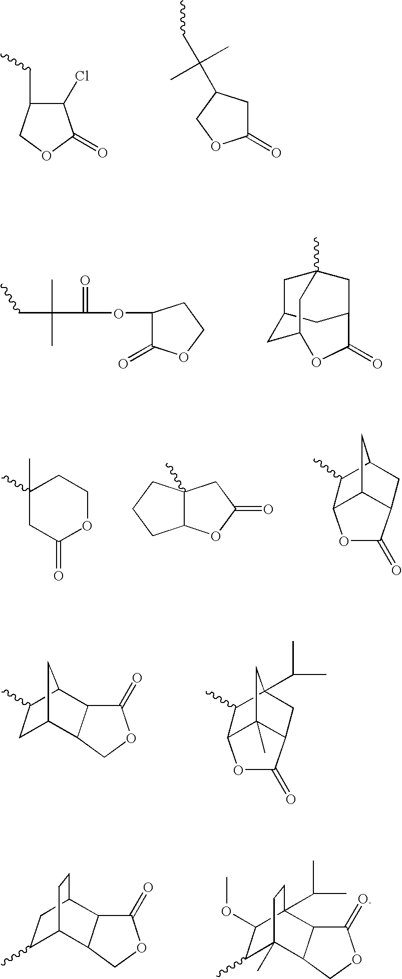

4. The polymer of claim 1 wherein R₃₃ is selected from

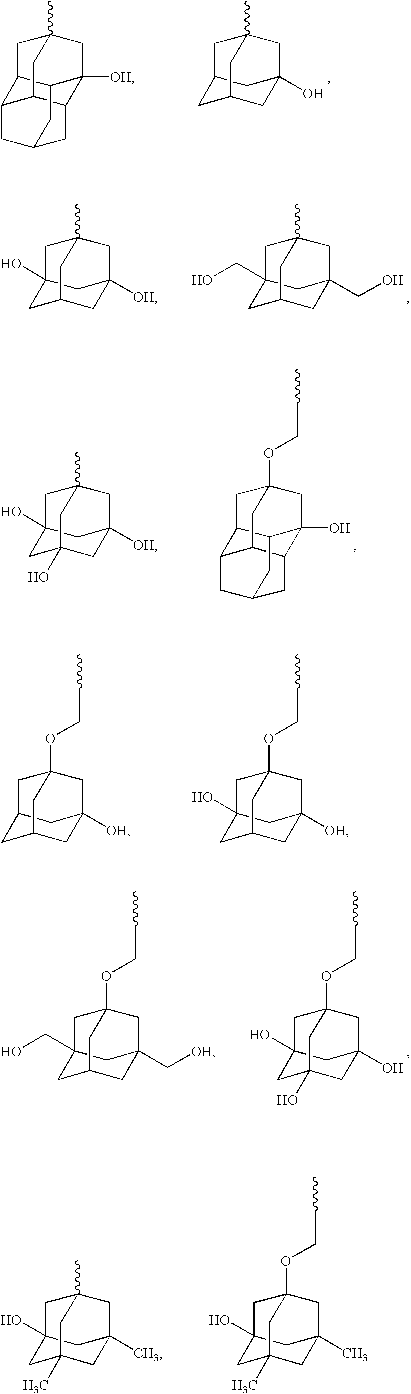

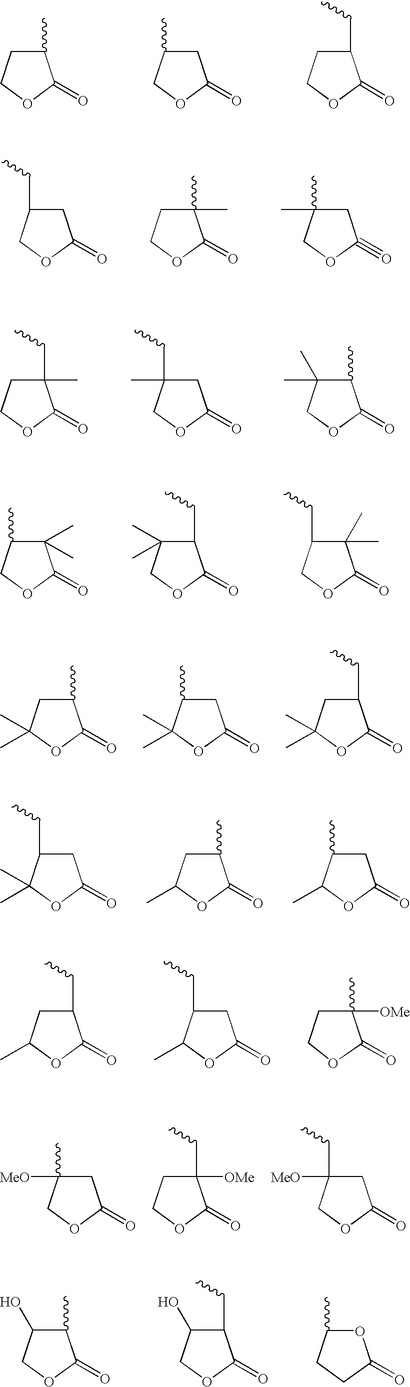

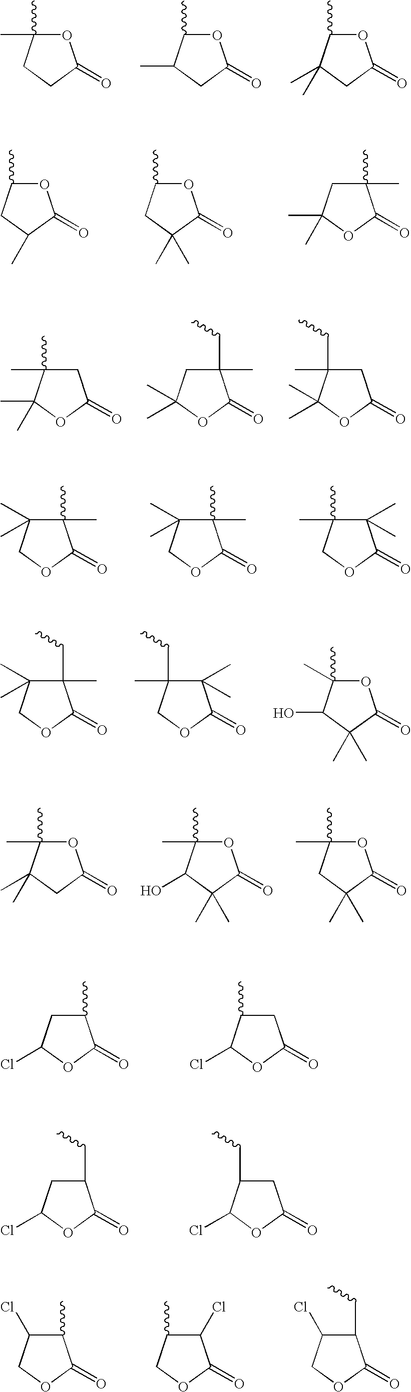

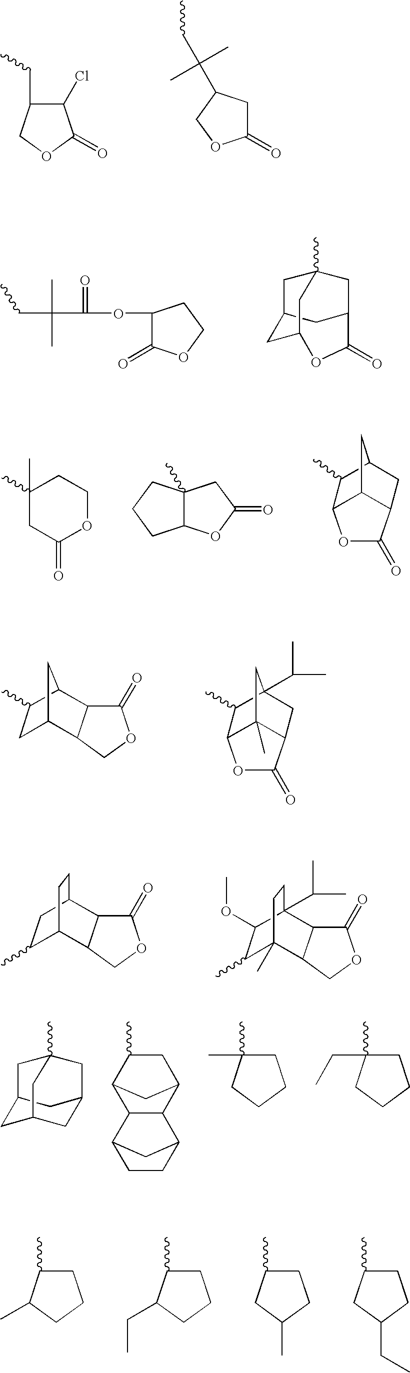

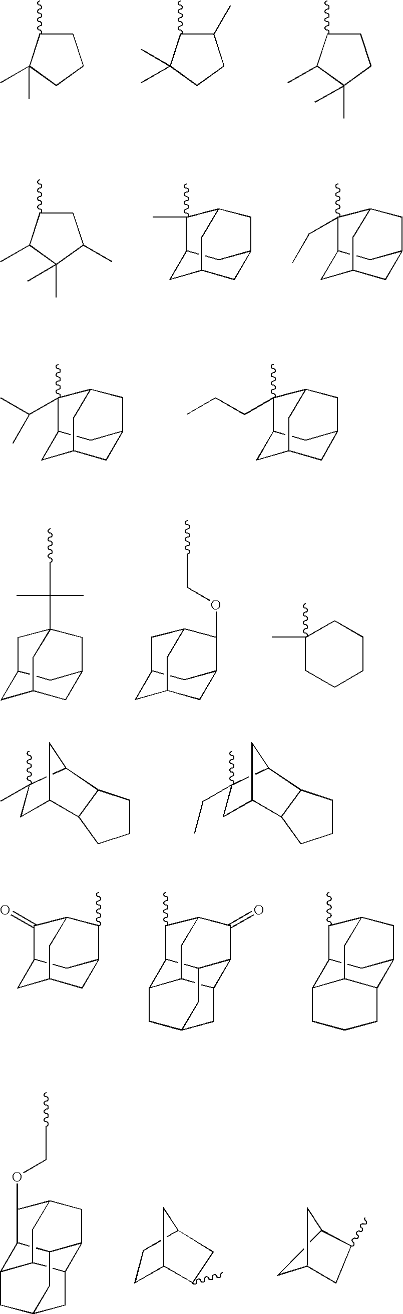

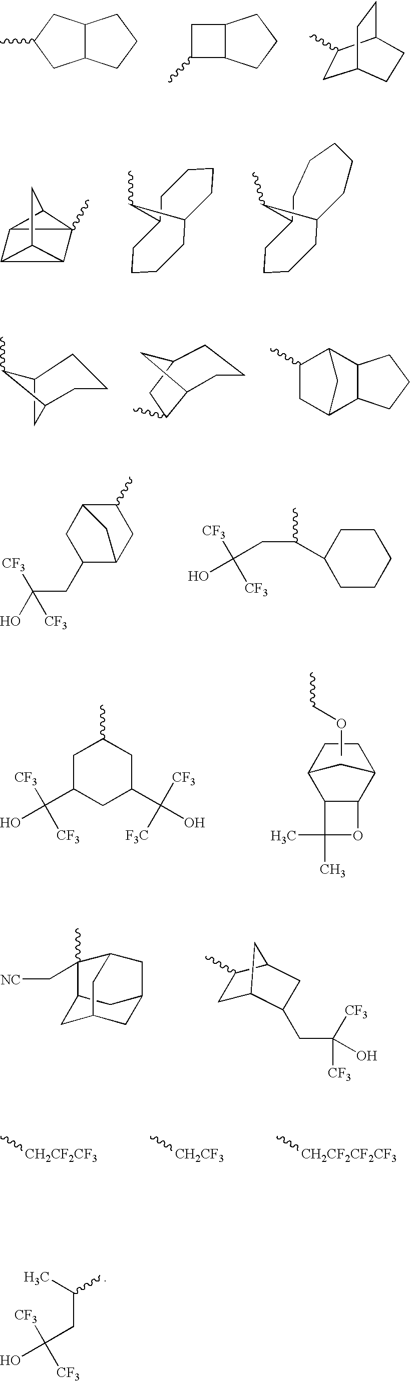

5. The polymer of claim 1 wherein jj is an integer ranging from 45 to 60.

6. The polymer of claim 1 wherein jj is an integer ranging from 45 to 60, kk is an integer ranging from 10 to 40, and mm is an integer ranging from 30 to 50.

7. The polymer of claim 1 selected from poly(2-ethyldiamantylmethacrylate-co-3-hydroxy-1-adamantyl acrylate-co-α-gamma-butyrolactone methacrylate), poly(2-ethyldiamantylmethacrylate-co-3-hydroxy-1-adamantyl acrylate-co-β-gamma-butyrolactone methacrylate), and poly(2-ethyldiamantylmethacrylate-co-3-hydroxy-1-adamantyl acrylate-co-α-gamma-butyrolactone acrylate).

8. A photoresist composition comprising:
(a) the polymer of claim 1;
(b) a mixture of compounds capable of producing acid upon irradiation.

9. The composition of claim 8 wherein (b) mixture of compounds of the following compounds:
(i) a compound of formula
(Ai)₂ Xi1,
where each Ai is individually an organic onium cation selected from 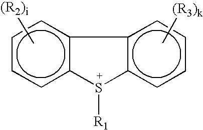
and
Y—Ar
where Ar is selected from 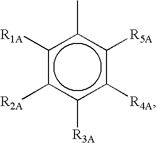
naphthyl, or anthryl;
Y is selected from 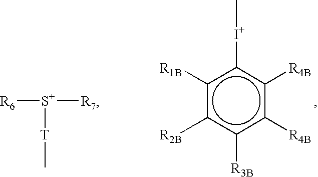
—I⁺-naphtyl, —I⁺-anthryl;
where R₁, R₂, R₃, R_{1A}, R_{1B}, R_{2A}, R_{2B}, R_{3A}, R_{3B}, R_{4A}, R_{4B}, R_{5A}, and R_{5B} are each independently selected from Z, hydrogen, OSO₂R₉, OR₂₀, straight or branched alkyl chain optionally containing one or more O atoms, monocycloalkyl or polycycloalkyl group optionally containing one or more O atoms, monocycloalkyl- or polycycloalkylcarbonyl group, aryl, aralkyl, arylcarbonylmethyl group, alkoxyalkyl, alkoxycarbonylalkyl, alkylcarbonyl, monocycloalkyl- or polycycloalkyloxycarbonylalkyl with the cycloalkyl ring optionally containing one or more O atoms, monocycloalkyl- or polycycloalkyloxyalkyl with the cycloalkyl ring optionally containing one or more O atoms, straight or branched perfluoroalkyl, monocycloperfluoroalkyl or polycycloperfluoroalkyl, straight or branched alkoxy chain, nitro, cyano, halogen, carboxyl, hydroxyl, sulfate, tresyl, or hydroxyl;
R₆ and R₇ are each independently selected from straight or branched alkyl chain optionally containing one or more O atoms, monocycloalkyl or polycycloalkyl group optionally containing one or more O atoms, monocycloalkyl- or polycycloalkylcarbonyl group, aryl, aralkyl, straight or branched perfluoroalkyl, monocycloperfluoroalkyl or polycycloperfluoroalkyl, arylcarbonylmethyl group, nitro, cyano, or hydroxyl or R₆ and R₇ together with the S atom to which they are attached form a 5-, 6-, or 7-membered saturated or unsaturated ring optionally containing one or more O atoms;
R₉ is selected from alkyl, fluoroalkyl, perfluoroalkyl, aryl, fluoroaryl, perfluoroaryl, monocycloalkyl or polycycloalkyl group with the cycloalkyl ring optionally containing one or more O atoms, monocyclofluoroalkyl or polycyclofluoroalkyl group with the cycloalkyl ring optionally containing one or more O atoms, or monocycloperfluoralkyl or polycycloperfluoroalkyl group with the cycloalkyl ring optionally containing one or more O atoms;
R₂₀ is alkoxyalkyl, alkoxycarbonylalkyl, alkylcarbonyl, monocycloalkyl- or polycycloalkyloxycarbonylalkyl with the cycloalkyl ring optionally containing one or more O atoms, or monocycloalkyl- or polycycloalkyloxyalkyl with the cycloalkyl ring optionally containing one or more O atoms;
T is a direct bond, a divalent straight or branched alkyl group optionally containing one or more O atoms, divalent aryl group, divalent aralkyl group, or divalent monocycloalkyl or polycycloalkyl group optionally containing one or more O atoms;
Z is —(V)ⱼ—(C(X11)(X12))ₙ—O—C(═O)—R₈, where either (i) one of X11 or X12 is straight or branched alkyl chain containing at least one fluorine atom and the other is hydrogen, halogen, or straight or branched alkyl chain or (ii) both of X11 and X12 are straight or branched alkyl chain containing at least one fluorine atom;
V is a linkage group selected from a direct bond, a divalent straight or branched alkyl group optionally containing one or more O atoms, divalent aryl group, divalent aralkyl group, or divalent monocycloalkyl or polycycloalkyl group optionally containing one or more O atoms;
X2 is hydrogen, halogen, or straight or branched alkyl chain optionally containing one or more O atoms;
R₈ is a straight or branched alkyl chain optionally containing one or more O atoms, a monocycloalkyl or polycycloalkyl group optionally containing one or more O atoms, or aryl;
X3 is hydrogen, straight or branched alkyl chain, halogen, cyano, or —C(═OR₅₀ where R₅₀ is selected from straight or branched alkyl chain optionally containing one or more O atoms or —O—R₅₁ where R₅₁ is hydrogen or straight or branched alkyl chain;
each of i and k are independently 0 or a positive integer;
j is 0 to 10;
m is 0 to 10;
and n is 0 to 10,
the straight or branched alkyl chain optionally containing one or more O atoms, straight or branched alkyl chain, straight or branched alkoxy chain, monocycloalkyl or polycycloalkyl group optionally containing one or more O atoms, monocycloalkyl- or polycycloalkylcarbonyl group, alkoxyalkyl, alkoxycarbonylalkyl, alkylcarbonyl, monocycloalkyl- or polycycloalkyloxycarbonylalkyl with the cycloalkyl ring optionally containing one or more O atoms, monocycloalkyl- or polycycloalkyloxyalkyl with the cycloalkyl ring optionally containing one or more O atoms, aralkyl, aryl, naphthyl, anthryl, 5-, 6-, or 7-membered saturated or unsaturated ring optionally containing one or more O atoms, or arylcarbonylmethyl group being unsubstituted or substituted by one or more groups selected from the group consisting of Z, halogen, alkyl, C₁₈ perfluoroalkyl, monocycloalkyl or polycycloalkyl, OR₂₀, alkoxy, C₃₋₂₀ cyclic alkoxy, dialkylamino, dicyclic dialkylamino, hydroxyl, cyano, nitro, tresyl, oxo, aryl, aralkyl, oxygen atom, CF₃SO₃, aryloxy, arylthio, and groups of formulae (II) to (VI): 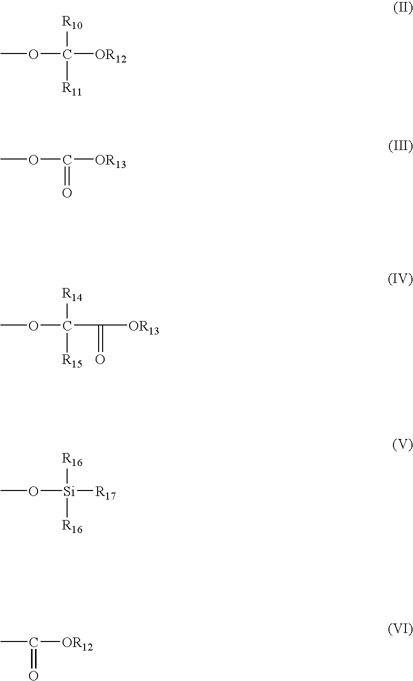
wherein R₁₀ and R₁₁ each independently represent a hydrogen atom, a straight or branched alkyl chain optionally containing one or more O atoms, or a monocycloalkyl or polycycloalkyl group optionally containing one or more O atoms, or R₁₀ and R₁₁ together can represent an alkylene group to form a five- or six-membered ring;
R₁₂ represents a straight or branched alkyl chain optionally containing one or more O atoms, a monocycloalkyl or polycycloalkyl group optionally containing one or more O atoms, or aralkyl, or R₁₀ and R₁₂ together represent an alkylene group which forms a five- or six-membered ring together with the interposing —C—O— group, the carbon atom in the ring being optionally substituted by an oxygen atom;
R₁₃ represents a straight or branched alkyl chain optionally containing one or more O atoms or a monocycloalkyl or polycycloalkyl group optionally containing one or more O atoms;
R₁₄ and R₁₅ each independently represent a hydrogen atom, a straight or branched alkyl chain optionally containing one or more O atoms or a monocycloalkyl or polycycloalkyl group optionally containing one or more O atoms;
R₁₆ represents a straight or branched alkyl chain optionally containing one or more O atoms, a monocycloalkyl or polycycloalkyl group optionally containing one or more O atoms, aryl, or aralkyl; and
R₁₇ represents straight or branched alkyl chain optionally containing one or more O atoms, a monocycloalkyl or polycycloalkyl group optionally containing one or more O atoms, aryl, aralkyl, the group —Si(R₁₆)₂R₁₇, or the group —O—Si(R₁₆)₂R₁₇, the straight or branched alkyl chain optionally containing one or more O atoms, monocycloalkyl or polycycloalkyl group optionally containing one or more O atoms, aryl, and aralkyl being unsubstituted or substituted as above;
Xi1 is an anion of the formula
Q-R₅₀₀—SO₃⁻
where Q is selected from O₃S and O₂C;
R₅₀₀ is a group selected from linear or branched alkyl, cycloalkyl, aryl, or combinations thereof, optionally containing a catenary O, S or N, where the alkyl, cycloalkyl, and aryl groups are unsubstituted or substituted by one or more groups selected from the group consisting of halogen, unsubstituted or substituted alkyl, unsubstituted or substituted C₁₈ perfluoroalkyl, hydroxyl, cyano, sulfate, and nitro; and
(ii) a compound of formula
Ai Xi2,
where Ai is an organic onium cation as previously defined and Xi2 is an anion.

10. The composition of claim 9 wherein Xi2 is selected from selected from CF₃SO₃⁻, CHF₂SO₃⁻, CH₃SO₃⁻, CCl₃SO₃⁻, C₂F₅SO₃⁻, C₂HF₄SO₃⁻, C₄F₉SO₃⁻, camphor sulfonate, perfluorooctane sulfonate, benzene sulfonate, pentafluorobenzene sulfonate, toluene sulfonate, perfluorotoluene sulfonate, (Rf1 SO₂)₃C⁻ and (Rf1 SO₂)₂N⁻, wherein each Rf1 is independently selected from the group consisting of highly fluorinated or perfluorinated alkyl or fluorinated aryl radicals and may be cyclic, when a combination of any two Rf1 groups are linked to form a bridge, further, the Rf1 alkyl chains contain from 1-20 carbon atoms and may be straight, branched, or cyclic, such that divalent oxygen, trivalent nitrogen or hexavalent sulfur may interrupt the skeletal chain, further when Rf1 contains a cyclic structure, such structure has 5 or 6 ring members, optionally, 1 or 2 of which are heteroatoms, and Rg-O—Rf2-SO₃⁻, where Rf2 is selected from the group consisting of linear or branched (CF₂)ⱼ where j is an integer from 4 to 10 and C₁-C₁₂ cycloperfluoroalkyl divalent radical which is optionally perfluoroC₁₋₁₀alkyl substituted, Rg is selected from the group consisting of C₁-C₂₀ linear, branched, monocycloalkyl or polycycloalkyl, C₁-C₂₀ linear, branched, monocycloalkenyl or polycycloalkenyl, aryl, and aralkyl, the alkyl, alkenyl, aralkyl and aryl groups being unsubstituted, substituted, optionally containing one or more catenary oxygen atoms, partially fluorinated or perfluorinated.

11. The composition of claim 10 wherein the anion Xi2 is selected from (C₂F₅SO₂)₂N⁻, (C₄F₉SO₂)₂N⁻, (C₈F₁₇SO₂)₃C⁻, (CF₃SO₂)₃C⁻, (CF₃SO₂)₂N⁻, (CF₃SO₂)₂(C₄F₉SO₂)C⁻, (C₂F₅SO₂)₃C⁻, (C₄F₉SO₂)₃C⁻, (CF₃SO₂)₂(C₂F₅SO₂)C⁻, (C₄F₉SO₂)(C₂F₅SO₂)₂C⁻, (CF₃SO₂)(C₄F₉SO₂)N⁻, [(CF₃)₂NC₂F₄SO₂]₂N⁻, (CF₃)₂NC₂F₄SO₂C⁻ (SO₂CF₃)₂, (3,5-bis(CF₃)C₆H₃)SO₂N⁻SO₂CF₃, C₆F₅SO₂C⁻(SO₂CF₃)₂, C₆F₅SO₂N⁻SO₂CF₃, 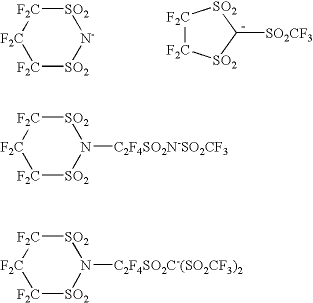
CF₃CHFO(CF₂)₄SO₃⁻, CF₃CH₂O(CF₂)₄SO₃⁻, CH₃CH₂O(CF₂)₄SO₃⁻, CH₃CH₂CH₂O(CF₂)₄SO₃⁻, C H₃O(CF₂)₄SO₃⁻, C₂H₅O(CF₂)₄SO₃⁻, C₄H₉O(CF₂)₄SO₃⁻, C₆H₅CH₂O(CF₂)₄SO₃⁻, C₂H₅OCF₂CF(CF₃)SO₃⁻, CH₂═CHCH₂O(CF₂)₄SO₃⁻, CH₃OCF₂CF(CF₃)SO₃⁻, C₄H₉OCF₂CF(CF₃)SO₃⁻, C₈H₁₇O(CF₂)₂SO₃⁻, and C₄H₉O(CF₂)₂SO₃⁻.

12. The composition of claim 8, wherein the compounds for mixture (b) are selected from the group bis(4-t-butylphenyl)iodonium triphenyl sulfonium perfluorobutane-1,4-disulfonate, bis(4-t-butylphenyl)iodonium triphenyl sulfonium perfluoropropane-1,3-disulfonate, bis(4-t-butylphenyl)iodonium triphenyl sulfonium perfluoropropane-1-carboxylate-3-sulfonate, bis(4-t-butylphenyl) iodonium triphenyl sulfonium perfluorobutane-1-carboxylate-4-sulfonate, bis(4-t-butylphenyl)iodonium triphenyl sulfonium perfluoromethane disulfonate, bis(4-t-butylphenyl)iodonium triphenyl sulfonium methane disulfonate, bis(4-t-butylphenyl)iodonium triphenyl sulfonium perfluoroethane disulfonate, bis(4-t-butylphenyl)iodonium triphenyl sulfonium ethane disulfonate, bis(triphenyl sulfonium)perfluorobutane-1,4-disulfonate, bis(triphenyl sulfonium) perfluoropropane-1,3-disulfonate, bis(benzoyltetramethylenesulfonium) perfluoropropane-1,3-disulfonate, bis(benzoyltetramethylenesulfonium) perfluorobutane-1,4-disulfonate, bis(tris(4-t-butylphenyl)sulfonium) perfluorobutane-1,4-disulfonate, bis(tris(4-t-butylphenyl)sulfonium) perfluoropropane-1,3-disulfonate, bis(4-t-butylphenyldiphenyl sulfonium) perfluorobutane-1,4-disulfonate, bis(4-t-butylphenyldiphenyl sulfonium) perfluoropropane-1,3-disulfonate, bis(triphenyl sulfonium)perfluoropropane-1-carboxylate-3-sulfonate, bis(triphenyl sulfonium)perfluorobutane-1-carboxylate-4-sulfonate, bis(benzoyltetramethylenesulfonium)perfluoropropane-1-carboxylate-3-sulfonate, bis(benzoyltetramethylenesulfonium)perfluorobutane-1-carboxylate-4-sulfonate, bis(tris(4-t-butyl phenyl)sulfonium)perfluoropropane-1-carboxylate-3-sulfonate, bis(tris(4-t-butyl phenyl)sulfonium)perfluorobutane-1-carboxylate-4-sulfonate, bis(4-t-butylphenyl diphenyl sulfonium) perfluoropropane-1-carboxylate-3-sulfonate, bis(4-t-butylphenyl diphenyl sulfonium)perfluorobutane-1-carboxylate-4-sulfonate, bis(4-t-butylphenyl iodonium)methane disulfonate, bis(triphenyl sulfonium)methane disulfonate, bis(4-t-butylphenyl iodonium)perfluoromethane disulfonate, bis(triphenyl sulfonium)perfluoromethane disulfonate, bis(benzoyltetramethylenesulfonium) perfluoromethane disulfonate, bis(benzoyl-tetramethylenesulfonium)methane disulfonate, bis(tris(4-t-butyl phenyl)sulfonium)perfluoromethane disulfonate, bis(tris(4-t-butyl phenyl)sulfonium)methane disulfonate, bis(4-t-butylphenyl diphenylsulfonium)perfluoromethane disulfonate, bis(4-t-butylphenyl diphenylsulfonium)methane disulfonate, bis(4-octyloxyphenyl)iodonium perfluorobutane-1,4-disulfonate, bis(4-octyloxyphenyl)iodonium ethane disulfonate, bis(4-octyloxyphenyl)iodonium perfluoroethane disulfonate, bis(4-octyloxyphenyl)iodonium perfluoropropane-1,3-disulfonate, bis(4-octyloxyphenyl) iodonium perfluoropropane-1-carboxylate-3-sulfonate, bis(4-octyloxyphenyl) iodonium perfluorobutane-1-carboxylate-4-sulfonate, bis(4-octyloxyphenyl) iodonium methane disulfonate, bis(4-octyloxyphenyl)iodonium perfluoromethane disulfonate, bis(4-octyloxyphenyl)phenyl sulfonium perfluorobutane-1,4-disulfonate, bis(4-octyloxyphenyl)phenyl sulfonium ethane disulfonate, bis(4-octyloxyphenyl)phenyl sulfonium perfluoroethane disulfonate, bis(4-octyloxyphenyl)phenyl sulfonium perfluoropropane-1,3-disulfonate, bis(4-octyloxyphenyl)phenyl sulfonium perfluoropropane-1-carboxylate-3-sulfonate, bis(4-octyloxyphenyl)phenyl sulfonium perfluorobutane-1-carboxylate-4-sulfonate, bis(4-octyloxyphenyl)phenyl sulfonium methane disulfonate, bis(4-octyloxyphenyl)phenyl sulfonium perfluoromethane disulfonate, bis[bis[4-pentafluorobenzenesulfonyloxy-phenyl]phenylsulfonium]perfluorobutane-1,4-disulfonate, bis[bis[4-pentafluoro-benzene-sulfonyloxyphenyl]phenylsulfonium]ethane disulfonate, bis[bis[4-pentafluorobenzenesulfonyloxyphenyl]phenylsulfonium]perfluoroethane disulfonate, bis[bis[4-pentafluorobenzenesulfonyloxyphenyl]phenylsulfonium]perfluoropropane-1,3-disulfonate, bis[bis[4-pentafluorobenzenesulfonyloxyphenyl]phenylsulfonium]perfluoropropane-1-carboxylate-3-sulfonate, bis[bis[4-pentafluorobenzenesulfonyloxy-phenyl]phenylsulfonium]perfluorobutane-1-carboxylate-4-sulfonate, bis[bis[4-pentafluorobenzenesulfonyloxyphenyl]phenylsulfonium]methane disulfonate, bis[bis[4-pentafluorobenzenesulfonyloxyphenyl]phenylsulfonium]perfluoromethane disulfonate, bis[bis[4-(3,5-di(trifluoromethyl)benzenesulfonyloxy)-phenyl]phenylsulfonium]perfluorobutane-1,4-disulfonate, bis[bis[4-(3,5-di(trifluoromethyl)-benzenesulfonyloxy)phenyl]phenylsulfonium]ethane disulfonate, bis[bis[4-(3,5-di(trifluoromethyl)benzenesulfonyloxy)phenyl]phenylsulfonium]perfluoroethane disulfonate, bis[bis[4-(3,5-di(trifluoromethyl)benzenesulfonyloxy)phenyl]phenylsulfonium]perfluoropropane-1,3-disulfonate, bis[bis[4-(3,5-di(trifluoromethyl)-benzenesulfonyloxy)phenyl]phenylsulfonium]perfluoropropane-1-carboxylate-3-sulfonate, bis[bis[4-(3,5-di(trifluoromethyl)benzenesulfonyloxy)-phenyl]phenylsulfonium]perfluorobutane-1-carboxylate-4-sulfonate, bis[bis[4-(3,5-di(trifluoromethyl)benzenesulfonyloxy)phenyl]phenylsulfonium]methane disulfonate, bis(4-t-butylphenyl iodonium) ethane disulfonate, bis(4-t-butylphenyl iodonium)perfluoroethane disulfonate, bis(triphenyl sulfonium)ethane disulfonate, bis(triphenyl sulfonium)perfluoroethane disulfonate, bis(benzoyltetramethylene-sulfonium)perfluoroethane disulfonate, bis(benzoyltetramethylenesulfonium)ethane disulfonate, bis(tris(4-t-butyl phenyl) sulfonium)perfluoroethane disulfonate, bis(tris(4-t-butyl phenyl)sulfonium) ethane disulfonate, bis(4-t-butylphenyl diphenyl-sulfonium)perfluoroethane disulfonate, bis(4-t-butylphenyl diphenylsulfonium)ethane disulfonate, bis[bis[2-methyladamantylacetyloxymethoxyphenyl]phenyl-sulfonium]perfluorobutane-1,4-disulfonate, bis[bis[2-methyladamantylacetyl-oxymethoxyphenyl]phenylsulfonium]ethane disulfonate, bis[bis[2-methyladamantylacetyloxymethoxyphenyl]phenylsulfonium]perfluoroethane disulfonate, bis[bis[2-methyladamantylacetyloxymethoxyphenyl]phenylsulfonium]perfluoro-propane-1,3-disulfonate, bis[bis[2-methyladamantylacetyloxymethoxyphenyl]phenylsulfonium]perfluoropropane-1-carboxylate-3-sulfonate, bis[bis[2-methyl-adamantylacetyloxymethoxyphenyl]phenylsulfonium]perfluorobutane-1-carboxylate-4-sulfonate, bis[bis[2-methyladamantylacetyloxymethoxyphenyl]phenylsulfonium]methane disulfonate, bis[bis[2-methyladamantylacetyloxy-methoxyphenyl]phenylsulfonium]perfluoromethane disulfonate, bis[bis[4,4-bis(trifluoromethyl)-3-oxatricyclo[4.2.1.0^{2,5}]-nonylmethoxyphenyl]phenyl sulfonium]perfluorobutane-1,4-disulfonate, bis[bis[4,4-bis(trifluoromethyl)-3-oxatricyclo-[4.2.1.0^{2,5}]-nonylmethoxy-phenyl]phenyl sulfonium]ethane disulfonate, bis[bis[4,4-bis(trifluoromethyl)-3-oxatricyclo[4.2.1.0^{2,5}]-nonylmethoxyphenyl]phenyl sulfonium]-perfluoroethane disulfonate, bis[bis[4,4-bis(trifluoromethyl)-3-oxatricyclo[4.2.1.0^{2,5}]-nonylmethoxy-phenyl]phenyl sulfonium]perfluoropropane-1,3-disulfonate, bis[bis[4,4-bis(trifluoro-methyl)-3-oxatricyclo[4.2.1.0^{2,5}]-nonylmethoxyphenyl]phenyl sulfonium]-perfluoropropane-1-carboxylate-3-sulfonate, bis[bis[4,4-bis(trifluoro-methyl)-3-oxatricyclo[4.2.1.0^{2,5}]-nonylmethoxyphenyl]phenyl sulfonium]perfluoro-butane-1-carboxylate-4-sulfonate, bis[bis[4,4-bis(trifluoromethyl)-3-oxatricyclo-[4.2.1.0^{2,5}]-nonylmethoxyphenyl]phenyl sulfonium]methane disulfonate, bis[bis[4,4-bis(trifluoromethyl)-3-oxatricyclo[4.2.1.0^{2,5}]-nonylmethoxyphenyl]phenyl sulfonium]perfluoromethane disulfonate, bis(4-t-butylphenyl)iodonium bis-perfluoroethane sulfonimide, diphenyliodonium trifluoromethane sulfonate, diphenyliodonium nonafluorobutane sulfonate, triphenylsulfonium trifluromethane sulfonate, triphenylsulfonium nonafluorobutane sulfonate, 4-(1-butoxyphenyl)diphenylsulfonium bis-(perfluorobutanesulfonyl)imide, 4-(1-butoxyphenyl)diphenylsulfonium bis-(perfluoroethanesulfonyl)imide, 2,4,6-trimethylphenyldiphenylsulfonium bis-perfluorobutanesulfonyl)imide, 2,4,6-trimethylphenyldiphenylsulfonium bis-(perfluoroethanesulfonyl)imide, toluenediphenylsulfonium bis-(perfluorobutanesulfonyl)imide, toluenediphenylsulfonium bis-(perfluoroethanesulfonyl)imide, toluenediphenylsulfonium-(trifluoromethyl perfluorobutylsulfonyl)imide, tris-(tert-butylphenyl)sulfonium-(trifluoromethyl perfluorobutylsulfonyl)imide, tris-(tert-butylphenyl)sulfonium bis-(perfluorobutanesulfonyl)imide, and tris-(tert-butylphenyl)sulfonium-bis-(trifluoromethanesulfonyl)imide.

13. A process for imaging a photoresist comprising the steps of: include
a) applying a coating layer a substrate with the composition of claim 8;
b) baking the substrate to substantially remove the solvent;
c) image-wise exposing the photoresist coating;
d) optionally, postexposure baking the photoresist coating; and
e) developing the photoresist coating with an aqueous alkaline solution.

14. A coated substrate comprising a substrate with a photoresist coating film, wherein the photoresist coating film is formed from the photoresist composition of claim 8.
